(19) United States
(12) Patent Application Publication
(10) Pub. No.: US 2024/0251603 A1
(43) Pub. Date: Jul. 25, 2024

(54) DISPLAY DEVICE AND METHOD OF MANUFACTURING THE SAME

(71) Applicant: Samsung Display Co., LTD., Yongin-si (KR)

(72) Inventors: GYEONGEUN EOH, Yongin-si (KR); SEON UK LEE, Yongin-si (KR); KANGUK KIM, Yongin-si (KR)

(73) Assignee: Samsung Display Co., LTD., Yongin-si (KR)

(21) Appl. No.: 18/405,376

(22) Filed: Jan. 5, 2024

(30) Foreign Application Priority Data
Jan. 19, 2023 (KR) 10-2023-0008359

(51) Int. Cl. H10K 59/122; H10K 59/12; H10K 59/38; H10K 59/80; H10K 71/10; H10K 71/13

(52) U.S. Cl. CPC H10K 59/122; H10K 59/1201; H10K 59/38; H10K 59/871; H10K 71/135; H10K 71/191

(57) ABSTRACT

A display device includes a first base substrate, a display structure, a second base substrate facing the first base substrate, a bank portion disposed between the first base substrate and the second base substrate in first and second areas and including openings overlapping the first and second areas, a color conversion layer disposed in the openings, and an alignment mark disposed in a corner opening among the openings disposed at at least one edge of the second area, positioned on a same line in a first direction as a center part of an opening adjacent to the corner opening among the openings in the first direction, and having a center part positioned on a same line in a second direction as a center part of an opening adjacent to the corner opening among the openings in the second direction intersecting the first direction.

### CROSS-REFERENCE TO RELATED APPLICATION

This application claims priority to and benefits of Korean Patent Application No. 10-2023-0008359 under 35 U.S.C. § 119, filed on Jan. 19, 2023 in the Korean Intellectual Property Office (KIPO), the entire contents of which are incorporated herein by reference.

### BACKGROUND

### 1. Technical Field

Embodiments provide generally to a display device. More particularly, embodiments relate to a display device and a method of manufacturing the same.

### 2. Description of the Related Art

A display device is a device that displays an image to provide visual information to a user. Among display devices, an organic light emitting diode (OLED) display has recently been attracting attention.

The display device may include a color conversion layer. The color conversion layer may convert a wavelength of light generated from the light emitting diode. The color conversion layer may be formed through an inkjet process. During the inkjet process, if the position of an inkjet apparatus cannot be corrected in real time, a misplaced defect may occur.

### SUMMARY

Embodiments provide a display device with improved reliability.

Embodiments provide a method of manufacturing the display device.

A display device according to embodiments of the disclosure includes a first area, a second area surrounding the first area, and a third area surrounding the second area, a first base substrate, a display structure disposed on the first base substrate in the first area, a second base substrate facing the first base substrate, a bank portion disposed between the first base substrate and the second base substrate in the first and second areas and including a plurality of openings in the first and second areas, a color conversion layer disposed in the plurality of openings, and an alignment mark disposed in a corner opening among the plurality of openings disposed at at least one edge of the second area, positioned on a same line in a first direction as a center part of an opening adjacent to the corner opening among the plurality of openings in the first direction, and having a center part positioned on a same line in a second direction as a center part of an opening adjacent to the corner opening among the plurality of openings in the second direction intersecting the first direction.

In an embodiment, the plurality of openings may include the corner opening at at least one corner of the second area, dummy openings in the second area excluding the corner opening, and pixel openings entirely overlapping the first area.

In an embodiment, each of the pixel openings may include first, second, and third sub-pixel openings adjacent to each other and each of the dummy openings may include first, second, and third sub-dummy openings adjacent to each other.

In an embodiment, a shape of the corner opening may be different from a shape of each of the first, second, and third sub-dummy openings and an area of the corner opening may be larger than an area of each of the first, second, and third sub-dummy openings in a plan view.

In an embodiment, the alignment mark may include first, second, and third alignment patterns adjacent to each other.

In an embodiment, a center part of the first alignment pattern may be positioned on a same line in the first direction as a center part of the first sub-dummy openings adjacent in the first direction and may be positioned on a same line in the second direction as a center part of the first sub-dummy opening adjacent in the second direction. A center part of the second alignment pattern may be positioned on a same line in the first direction as a center part of the second sub-dummy openings adjacent in the first direction and may be positioned on a same line in the second direction as a center part of the second sub-dummy opening adjacent in the second direction. A center part of the third alignment pattern may be positioned on a same line in the first direction as a center part of the third sub-dummy openings adjacent in the first direction and may be positioned on a same line in the second direction as a center part of the third sub-dummy opening adjacent in the second direction.

In an embodiment, each of the first, second, and third alignment pattern may have a cross shape.

In an embodiment, the display device may further include a sealing member disposed between the first base substrate and the second base substrate.

In an embodiment, the sealing member may be disposed in the third area.

In an embodiment, the alignment mark may include a same material as the bank portion.

In an embodiment, the bank portion and the alignment mark may be integral with each other.

In an embodiment, the color conversion may include quantum dots.

A display device according to embodiments of the disclosure includes a first area, a second area surrounding the first area, and a third area surrounding the second area, a first base substrate, a display structure disposed on the first base substrate in the first area, a second base substrate facing the first base substrate, a bank portion disposed between the first base substrate and the second base substrate in the first and second areas and including a plurality of openings in the first and second areas, a color conversion layer disposed in the plurality of openings, and an alignment mark disposed in a corner opening among the plurality of openings disposed at at least one corner of the second area and protruding in a direction from the bank portion to the corner opening.

In an embodiment, the alignment mark may be integral with the bank portion.

In an embodiment, the plurality of openings may include the corner opening at at least one corner of the second area, dummy openings in the second area excluding the corner opening, and pixel openings entirely overlapping the first area.

In an embodiment, the corner opening may include first, second, and third sub-corner openings adjacent to each other, each of the pixel openings may include first, second, and third sub-pixel openings adjacent to each other, and each of the dummy openings may include first, second, and third sub-dummy openings adjacent to each other.

In an embodiment, shapes of the first, second, and third sub-corner openings may be a same as shapes of the first, second, and third sub-dummy openings, respectively.

In an embodiment, the alignment mark include at least one alignment pattern disposed in each of the first, second, and third sub-corner openings.

In an embodiment, a shape of the alignment pattern may be a triangle or a quadrangle.

In an embodiment, the alignment mark may protrude from a side surface of the bank portion.

A method of manufacturing a display device according to embodiments of the disclosure includes forming a display structure on a first base substrate in a first area, forming a bank portion on a second base substrate, the bank portion including a plurality of openings in the first area and a second area surrounding the first area, forming an alignment mark disposed in a corner opening among the plurality of openings disposed at at least one edge of the second area, positioned on a same line in a first direction as a center part of an opening adjacent to the corner opening among the plurality of openings in the first direction, and having a center part positioned on a same line in a second direction as a center part of an opening adjacent to the corner opening among the plurality of openings in the second direction intersecting the first direction, forming a color conversion layer in the plurality of openings in the first and second areas, and adhering the first base substrate and the second base substrate.

In an embodiment, the bank portion and the alignment mark may be integral with each other.

In an embodiment, the forming of the bank portion and the forming of the alignment mark may be simultaneously performed.

In an embodiment, the bank portion and the alignment mark may be formed using a slit mask.

In an embodiment, the plurality of openings may include the corner opening formed at at least one corner of the second area, dummy openings formed in the second area excluding the corner opening, and pixel openings entirely overlapping the first area.

In an embodiment, each of the pixel openings may include first, second, and third sub-pixel openings adjacent to each other and each of the dummy openings may include first, second, and third sub-dummy openings adjacent to each other.

In an embodiment, the forming of the alignment mark may include forming first, second, and third alignment patterns adjacent to each other. A center part of the first alignment pattern may be formed on a same line in the first direction as a center part of the first sub-dummy openings adjacent in the first direction and may be formed on a same line in the second direction as a center part of the first sub-dummy opening adjacent in the second direction. A center part of the second alignment pattern may be formed on a same line in the first direction as a center part of the second sub-dummy openings adjacent in the first direction and may be formed on a same line in the second direction as a center part of the second sub-dummy opening adjacent in the second direction. A center part of the third alignment pattern may be formed on a same line in the first direction as a center part of the third sub-dummy openings adjacent in the first direction and may be formed on a same line in the second direction as a center part of the third sub-dummy opening adjacent in the second direction.

In an embodiment, the color conversion layer may be formed by an inkjet process.

In a display device according to embodiments, the display device may further include an alignment mark disposed in corner openings. The alignment mark may indicate a starting point in an inkjet process. Accordingly, the inkjet process may be started from the position where the alignment mark is disposed. In addition, in case that a color conversion layer is formed by the inkjet apparatus, the position of the inkjet apparatus may be corrected by using the alignment mark whenever ink is printed on a plurality of openings of a bank portion. Accordingly, defects of the display device due to misplacement during the inkjet process may be prevented and reliability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment of the disclosure.

FIG. 2 is a schematic cross-sectional view taken along line I-I′ of FIG. 1.

FIG. 3 is a schematic cross-sectional view taken along line II-II′ of FIG. 1.

FIG. 4 is a schematic cross-sectional view illustrating another example of FIG. 3.

FIG. 5 is a schematic enlarged plan view of area A of FIG. 1.

FIG. 6 is a schematic enlarged plan view of area B of FIG. 5.

FIGS. 7 and 8 are schematic plan views illustrating other examples of FIG. 6.

FIG. 9 is a schematic plan view illustrating another example of FIG. 5.

FIG. 10 is a schematic enlarged plan view of area C of FIG. 9.

FIG. 11 is a schematic plan view illustrating another example of FIG. 10.

FIG. 12 is a schematic cross-sectional view taken along line III-III′ of FIG. 10.

FIG. 13 is a schematic cross-sectional view illustrating another example of FIG. 12.

FIGS. 14 and 15 are schematic plan views illustrating other examples of FIG. 10.

FIGS. 16, 17, 18, 19, 20, 21, 22, and 23 are schematic views illustrating a method of manufacturing a display device according to an embodiment.

### DETAILED DESCRIPTION OF THE EMBODIMENTS

Hereinafter, a display device according to embodiments of the disclosure will be explained in detail with reference to the accompanying drawings. The same reference numerals are used for the same components in the drawings, and redundant descriptions of the same components will be omitted.

In this specification, a plane may be defined as a first direction DR1 and a second direction DR2 crossing the first direction DR1. For example, the first direction DR1 and the second direction DR2 may be perpendicular to each other. A direction normal to the plane, e.g., a thickness direction of the display device 10 may be a third direction DR3. In other words, the third direction DR3 may be perpendicular to each of the first and second directions DR1 and DR2.

In this specification, in case that an element is “in” an area, it should be understood that the element is disposed at least in the area or overlaps at least part of the area.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

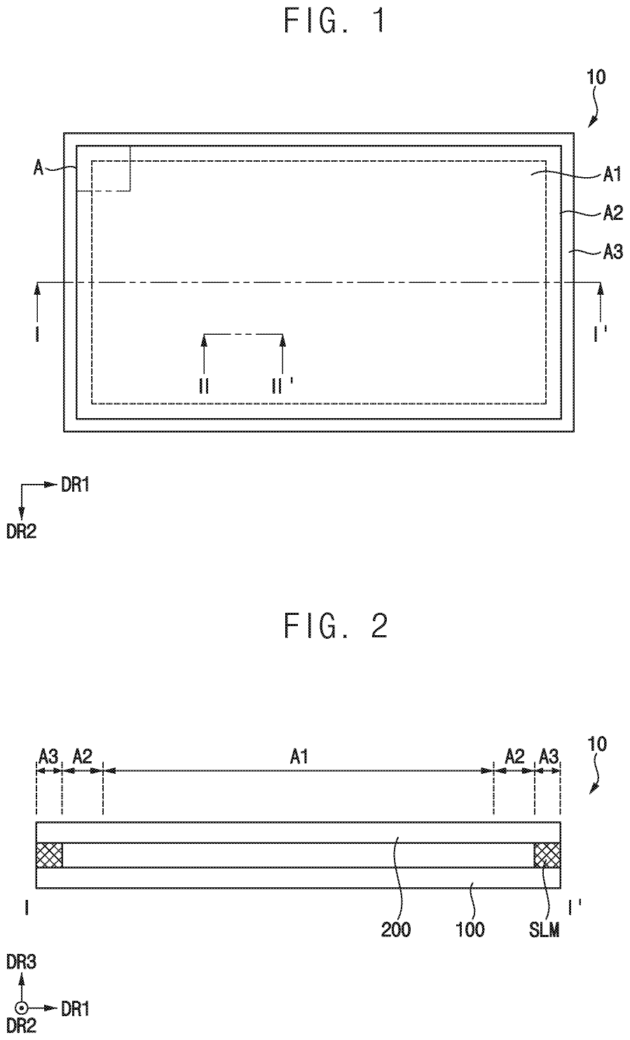

FIG. 1 is a schematic plan view illustrating a display device according to an embodiment of the disclosure. FIG. 2 is a thickness direction cross-sectional view taken along line I-I′ of FIG. 1.

Referring to FIGS. 1 and 2, a display device 10 may include a first substrate 100, a sealing member SLM, and a second substrate 200. The second substrate 200 may face the first substrate 100. The second substrate 200 may be positioned in the third direction DR3 from the first substrate 100. For example, the third direction DR3 may be a front direction of the display device 10 from the first substrate 100.

The sealing member SLM may be disposed between the first substrate 100 and the second substrate 200. The sealing member SLM may couple the first substrate 100 and the second substrate 200 together. The sealing member SLM may overlap a third area A3.

The display device 10 may include a first area A1 where an image is displayed, a second area A2 surrounding the first area A1, and the third area A3 surrounding the second area A2. For example, the first area A1 may be a display area, and the second area A2 and the third area A3 may be non-display areas. Specifically, the third area A3 may be a sealing area. However, the disclosure is not limited thereto.

The first substrate 100 may include a display structure and may be referred to as a display substrate. The display structure may include pixels. The pixels may be disposed in the first area A1 of the first substrate 100. However, the disclosure is not limited thereto, and the display structure may be disposed even in the second area A2.

Each of the pixels may include a driving element and a light emitting diode. The driving element may include at least one thin film transistor. The light emitting diode may generate light according to a driving signal. For example, the light emitting diode may be an inorganic light emitting diode or an organic light emitting diode.

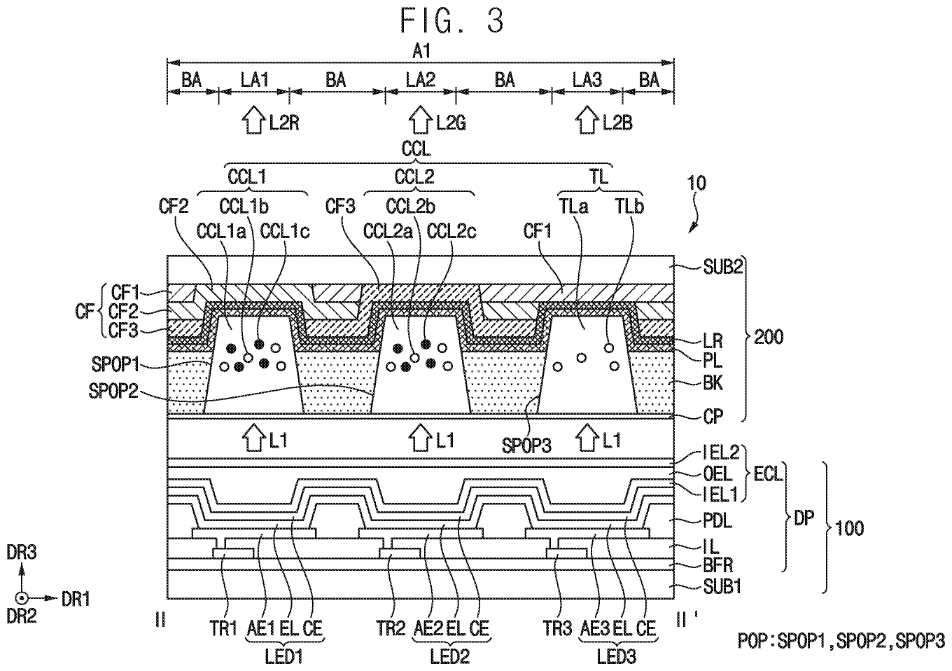

The second substrate 200 may include a color conversion layer (e.g., a color conversion layer CCL of FIG. 3) and may be referred to as a color conversion substrate. The color conversion layer may be disposed in the first area A1 and may convert a wavelength of light generated from the light emitting diode of the first substrate 100. The second substrate 200 may further include a color filter layer that transmits light of a specific color.

The sealing member SLM may be disposed between the first substrate 100 and the second substrate 200 and may be disposed in the second area A2. For example, the sealing member SLM may be disposed in the second area A2 between the first substrate 100 and the second substrate 200 so as to surround the first area A1 in a plan view.

For example, the sealing member SLM may have a hollow rectangular planar shape. However, the disclosure is not limited thereto, and the sealing member SLM may have various planar shapes according to the planar shape of the first substrate 100 or the second substrate 200. For example, when the first substrate 100 or the second substrate 200 has a planar shape such as a triangle, a rhombus, a polygon, a circle, or an ellipse, the sealing member SLM may have a planar shape such as a hollow triangle, a hollow rhombus, a hollow polygon, a hollow circle, or a hollow ellipse.

A filling layer may be disposed between the first substrate 100 and the second substrate 200. For example, the filling layer may act as a buffer against external pressure applied to the display device 10. For example, the filling layer may maintain a gap between the first substrate 100 and the second substrate 200. However, the disclosure is not limited thereto.

FIG. 3 is a schematic cross-sectional view taken along line II-II' of FIG. 1.

Referring to FIGS. 1, 2, and 3, the first area A1 may include a light emitting area and a light blocking area BA. Light (hereinafter, incident light) L1 generated from the first substrate 100 and incident to the second substrate 200 may be emitted to the outside through the light emitting area. The light emitting area may include first, second, and third light emitting areas LA1, LA2, and LA3 for emitting light of different colors. For example, a first transmitted light L2R having a red color may be emitted from the first light emitting area LA1, a second transmitted light L2G having a green color may be emitted from the second light emitting area LA2, and a third transmitted light L2B having a blue color may be emitted from the third light emitting area LA3.

In an embodiment, the first, second, and third light emitting areas LA1, LA2, and LA3 may be spaced apart from each other in a plan view and may be arranged to repeat each other. The light blocking area BA may surround the first, second, and third light emitting areas LA1, LA2, and LA3 in a plan view. For example, the light blocking area BA may have a grid shape in a plan view.

In an embodiment, the first substrate 100 may include a first base substrate SUB1 and a display structure DP. The display structure DP may be disposed on the first base substrate SUB1 and may overlap the first area A1. Since the display structure DP emits light, the first area A1 may be a display area. The display structure DP may include a buffer layer BFR, first, second, and third driving elements TR1, TR2, and TR3, an insulating layer IL, a pixel defining layer PDL, first to third light emitting diodes LED1, LED2, and LED3, and an encapsulation layer ECL.

The first base substrate SUB1 may include the first area A1, the second area A2, and the third area A3 as the display device 10 includes the first area A1, the second area A2, and the third area A3.

The first base substrate SUB1 may be an insulating substrate formed of a transparent or opaque material. In an embodiment, the first base substrate SUB1 may include glass. The first substrate 100 may be a rigid display substrate. In another embodiment, the first base substrate SUB1 may include plastic. The first substrate 100 may be a flexible display substrate.

The buffer layer BFR may be disposed on the first base substrate SUB1. The buffer layer BFR may prevent impurities such as oxygen and moisture from diffusing onto the first base substrate SUB1 through the first base substrate SUB1. The buffer layer BFR may include an inorganic material such as a silicon compound, a metal oxide, and the like. The buffer layer BFR may have a single-layer structure or a multi-layer structure including insulating layers.

The first, second, and third driving elements TR1, TR2, and TR3 may be disposed in the first area A1 on the buffer layer BFR. Each of the first, second, and third driving elements TR1, TR2, and TR3 may include at least one thin film transistor. The channel layer of the thin film transistor may include an oxide semiconductor, a silicon semiconductor, or an organic semiconductor. For example, the oxide semiconductor may include, e.g., at least one oxide of indium (In), gallium (Ga), tin (Sn), zirconium (Zr), vanadium (V), hafnium (Hf), cadmium (Cd), germanium (Ge), chromium (Cr), titanium (Ti), zinc (Zn), and the like. The silicon semiconductor may include, e.g., at least one of amorphous silicon, polycrystalline silicon, and the like.

The insulating layer IL may cover the first, second, and third driving elements TR1, TR2, and TR3. The insulating layer IL may include a combination of an inorganic insulating layer and an organic insulating layer.

The first, second, and third light emitting diodes LED1, LED2, and LED3 may be disposed on the insulating layer IL. For example, first, second, and third pixel electrodes AE1, AE2, and AE3 may be disposed on the insulating layer IL. Each of the first, second, and third pixel electrodes AE1, AE2, and AE3 may include, e.g., at least one of a conductive material such as a metal, an alloy, a conductive metal nitride, a conductive metal oxide, a transparent conductive material, and the like. Each of the first, second, and third pixel electrodes AE1, AE2, and AE3 may have a single-layer structure or a multi-layer structure including conductive layers.

The first, second, and third pixel electrodes AE1, AE2, and AE3 may be electrically connected to the first, second, and third driving elements TR1, TR2, and TR3 through contact holes formed in the insulating layer IL, respectively.

The pixel defining layer PDL may be disposed on the first, second, and third pixel electrodes AE1, AE2, and AE3. The pixel defining layer PDL may include an organic material. The pixel defining layer PDL may define a pixel opening exposing at least a part of each of the first, second, and third pixel electrodes AE1, AE2, and AE3.

A light emitting layer EL may be disposed on the first, second, and third pixel electrodes AE1, AE2, and AE3 exposed by the pixel opening of the pixel defining layer PDL. In an embodiment, the light emitting layer EL may continuously extend on the first area A1 over pixels. In another embodiment, the light emitting layer EL may be separated from the light emitting layer of an adjacent pixel.

The light emitting layer EL may include at least one of an organic light emitting material and quantum dots. In an embodiment, the light emitting layer EL may generate blue light. However, embodiments of the disclosure are not limited thereto. In another embodiment, the light emitting layer EL may generate red light or green light, or may generate lights having different colors according to pixels.

For example, all of the light emitting layers EL may include an organic material for emitting blue light. The light emitting layer EL may be formed in multiple layers and may have a structure in which blue organic light emitting layers are stacked each other. For example, the light emitting layer EL may have a structure in which three blue organic light emitting layers are stacked each other.

However, embodiments according to the disclosure are not limited thereto, and the light emitting layer EL may have a structure in which blue organic light emitting layers and an organic light emitting layer that emits light of different colors are stacked each other. For example, the light emitting layer EL may have a structure in which three blue organic light emitting layers and a green organic light emitting layer are stacked each other. In an embodiment, functional layers such as a hole injection layer, a hole transport layer, an electron transport layer, and an electron injection layer may be disposed above and/or below the light emitting layer EL.

A common electrode CE may be disposed on the light emitting layer EL. The common electrode CE may include a conductive material such as a metal, an alloy, a conductive metal nitride, a conductive metal oxide, a transparent conductive material, and the like. The common electrode CE may have a single-layer structure or a multi-layer structure including conductive layers. In an embodiment, the common electrode CE may continuously extend on the first area A1 over the pixels.

The first pixel electrode AE1, the light emitting layer EL, and the common electrode CE may form the first light emitting diode LED1, the second pixel electrode AE2, the light emitting layer EL, and the common electrode CE may form the second light emitting diode LED2, and the third pixel electrode AE3, the light emitting layer EL, and the common electrode CE may form the third light emitting diode LED3.

The encapsulation layer ECL may be disposed on the common electrode CE. The encapsulation layer ECL may include at least one inorganic encapsulation layer and at least one organic encapsulation layer. In an embodiment, the encapsulation layer ECL may include a first inorganic encapsulation layer IEL1 disposed on the common electrode CE, an organic encapsulation layer OEL disposed on the first inorganic encapsulation layer IEL1, and a second inorganic encapsulation layer IEL2 disposed on the organic encapsulation layer OEL.

In an embodiment, the second substrate 200 may include a second base substrate SUB2, a color filter layer CF, a bank portion (or bank part) BK, a color conversion layer CCL, a low refractive index layer LR, a protective layer PL, and capping layer CP.

The second base substrate SUB2 may face the first base substrate SUB1. The second base substrate SUB2 may include the first area A1, the second area A2, and the third area A3 as the display device 10 includes the first Area A1, the second area A2, and the third area A3.

The second base substrate SUB2 may be an insulating substrate made of a transparent material. The second base substrate SUB2 may include glass or plastic.

The color filter layer CF may be disposed under the second base substrate SUB2. For example, the color filter layer CF may be disposed under the second base substrate SUB2 and may overlap the first area A1, the second area A2, and the third area A3. The color filter layer CF may include a first color filter pattern CF1, a second color filter pattern CF2, and a third color filter pattern CF3.

The first color filter pattern CF1 may overlap the third light emitting area LA3 and may selectively transmit blue light. The second color filter pattern CF2 may overlap the first light emitting area LA1 and may selectively transmit red light. The third color filter pattern CF3 may overlap the second light emitting area LA2 and s may selectively transmit green light.

In an embodiment, each of the first color filter pattern CF1, the second color filter pattern CF2, and the third color filter pattern CF3 may be disposed to more overlap the blocking area BA. For example, as illustrated in FIG. 3, the second color filter pattern CF2 may overlap the first light emitting area LA1 and the light blocking area BA, and may not overlap the second and third light emitting areas LA2 and LA3. The third color filter pattern CF3 may overlap the second light emitting area LA2 and the blocking area BA, and may not overlap the first and third light emitting areas LA1 and LA3. The first color filter pattern CF1 may overlap the third light emitting area LA3 and the blocking area BA, and may not overlap the first and second light emitting areas LA1 and LA2. In the blocking area BA, portions of the first, second, and third color filter patterns CF1, CF2, and CF3 may overlap each other in the third direction DR3. Accordingly, color mixing between the adjacent first, second, and third light emitting areas LA1, LA2, and LA3 may be prevented.

The color filter layer CF may be disposed under the second base substrate SUB2 and may selectively overlap the second area A2 and the third area A3. For example, the color filter layer CF may extend from the first area A1 to the second area A2 and the third area A3.

A portion of the color filter layer CF overlapping the second area A2 and the third area A3 may serve as a light blocking member. The third color filter pattern CF3, the second color filter pattern CF2, and the first color filter pattern CF1 may be disposed overlapping in the direction DR3 in the second area A2 and the third area A3. Accordingly, in the second area A2 and the third area A3, the color filter layer CF may effectively block light traveling in the third direction DR3.

In the second area A2 and the third area A3, the color filter layer CF may prevent circuit structures such as lines and driving circuits disposed in the second area A2 of the second substrate 200 from being viewed from the outside of the display device 10. The color filter layer CF may prevent a light leakage phenomenon in which light reflected from the circuit structures or light emitted from the first area A1 is emitted through the second area A2 and the third area A3 of the second base substrate SUB2.

The low refractive index layer LR may be disposed under the color filter layer CF and may entirely cover the color filter layer CF. The low refractive index layer LR may have a lower refractive index than the capping layer CP. The low refractive index layer LR may increase light extraction efficiency and increase the luminance and lifespan of the display device 10. For example, the low refractive index layer LR may include an organic material.

The protective layer PL may be disposed under the low refractive index layer LR. The protective layer PL may cover the low refractive index layer LR. For example, the protective layer PL may include an inorganic material.

In an embodiment, the bank portion BK may be disposed under the protective layer PL. For example, the bank portion BK may be disposed between the first base substrate SUB1 and the second base substrate SUB2. The bank portion BK may overlap the first area A1 and the second area A2. However, the disclosure is not limited thereto, and the bank portion BK may extend to the third area A3. The bank portion BK may define openings.

The openings may overlap the first area A1 and the second area A2. For example, as illustrated in FIG. 3, the openings of the bank portion BK may include pixel openings POP overlapping the first area A1. The pixel openings POP may include first, second, and third sub-pixel openings SPOP1, SPOP2, and SPOP3. The first, second, and third sub-pixel openings SPOP1, SPOP2, and SPOP3 may expose the first, second, and third light emitting areas LA1, LA2, and LA3, respectively. The bank portion BK may form a space capable of accommodating an ink composition in the process of forming the color conversion layer CCL. For example, the bank portion BK may entirely overlap the light blocking area BA and may have a grid shape in a plan view.

The bank portion BK may include an organic material. In an embodiment, the bank portion BK may further include a light blocking material. For example, at least a part of the bank portion BK may include a light-blocking material such as black pigment, dye, carbon black, and the like.

In an embodiment, the color conversion layer CCL may be disposed under the protective layer PL and may overlap the first area A1. However, the disclosure is not limited thereto, and the color conversion layer CCL may also overlap the second area A2.

The color conversion layer CCL may be disposed in the pixel openings POP. The color conversion layer CCL may include color conversion portions disposed spaced apart from each other on a lower surface of the protective layer PL. In an embodiment, the color conversion layer CCL may include a first color conversion portion (or first color conversion part) CCL1, a second color conversion portion CCL2, and a transmission portion TL. The first color conversion portion CCL1, the second color conversion portion CCL2, and the transmission portion TL may be disposed in the first area A1 under the color filter layer CF, and may overlap the first, second, and third light emitting areas LA1, LA2, and LA3, respectively. For example, the first color conversion portion CCL1, the second color conversion portion CCL2, and the transmission portion TL may be disposed the first, second, and third sub-pixel openings SPOP1, SPOP2, and SPOP3 of the bank portion BK, respectively.

The first color conversion portion CCL1 may overlap the first light emitting area LA1. The first color conversion portion CCL1 may convert the incident light L1 into the first transmitted light L2R having red color. For example, the first color conversion portion CCL1 may include a resin portion CCL1a, a scattering material CCL1b, and a wavelength conversion particle CCL1c.

The scattering material CCL1b may increase an optical path by scattering the incident light L1 without substantially changing the wavelength of the incident light L1 incident on the first color conversion portion CCL1. The scattering material CCL1b may include a metal oxide or an organic material. As another example, the scattering material CCL1b may be omitted.

In an embodiment, the wavelength conversion particle CCL1c may include quantum dots. The quantum dot may be defined as a semiconductor material having nanocrystals. The quantum dot has a specific band gap depending on its composition and size. Accordingly, the quantum dot may absorb the incident light L1 and emit light having a different wavelength from a wavelength of the incident light L1. For example, the quantum dot may have a diameter of about 100 nm or less, and specifically may have a diameter of about 1 nm to about 20 nm. For example, the wavelength conversion particle CCL1c of the first color conversion portion CCL1 may include quantum dots that absorbs the incident light L1 and emits red light.

The scattering material CCL1b and the wavelength conversion particle CCL1c may be disposed in the resin portion (or resin part) CCL1a. For example, the resin portion CCL1a may include, e.g., an epoxy-based resin, an acrylic-based resin, a phenol-based resin, a melamine-based resin, a cardo-based resin, an imide-based resin, the like, or a combination thereof.

The first color conversion portion CCL1 may convert the incident light L1 to emit the first transmitted light L2R having red color. The incident light L1 not converted by the first color conversion portion CCL1 may be blocked by the second color filter pattern CF2. Accordingly, in the first light emitting area LA1, the first transmitted light L2R having red color may pass through the second base substrate SUB2 and may be emitted to the outside (e.g., in the third direction DR3).

The second color conversion portion CCL2 may overlap the second light emitting area LA2. The second color conversion portion CCL2 may convert the incident light L1 into the second transmitted light L2G having the green color. For example, the second color conversion portion CCL2 may include a resin portion CCL2a, a scattering material CCL2b, and a wavelength conversion particle CCL2c. The resin portion CCL2a and the scattering material CCL2b of the second color conversion portion CCL2 may be substantially the same as or similar to the resin portion CCL1a and the scattering material CCL1b of the first color conversion portion CCL1.

For example, the wavelength conversion particle CCL2c of the second color conversion portion CCL2 may include quantum dots that absorbs the incident light L1 and emits green light. Accordingly, the second color conversion portion CCL2 may convert the incident light L1 to emit the second transmitted light L2G having the green color. The incident light L1 not converted by the second color conversion portion CCL2 may be blocked by the third color filter pattern CF3. Accordingly, in the second light emitting area LA2, the second transmitted light L2G having the green color may pass through the second base substrate SUB2 and may be emitted to the outside (e.g., in the third direction DR3).

The transmission portion TL may overlap the third light emitting area LA3. The transmission portion TL may transmit the incident light L1 to emit the third transmitted light L2B. For example, the transmission portion TL may include a resin portion TLa and a scattering material TLb. The resin portion TLa and the scattering material TLb of the transmission portion TL may be substantially the same as or similar to the resin portion CCL1a and the scattering material CCL1b of the first color conversion portion CCL1.

However, the disclosure is not limited thereto, and the transmission portion TL may convert the incident light L1 into the third transmitted light L2B having the blue color. The transmission portion TL may further include wavelength conversion particles including quantum dots that absorb the incident light L1 and emit blue light.

A portion of the incident light L1 may be blocked by the first color filter pattern CF1. Accordingly, in the third light emitting area LA3, the third transmitted light L2B having blue color may pass through the second base substrate SUB2 and may be emitted to the outside (e.g., in the third direction DR3).

As the first, second, and third transmitted lights L2R, L2G, and L2B emitted to the outside through the second base substrate SUB2 are combined in the first, second, and third light emitting areas LA1, LA2, and LA3, the image may be displayed in the first area A1.

The capping layer CP may be disposed under the bank portion BK and the color conversion layer CCL. The capping layer CP may protect the color conversion layer CCL from, e.g., oxygen, moisture, foreign substances, and the like. For example, the capping layer CP may cover the bank portion BK and the color conversion layer CCL.

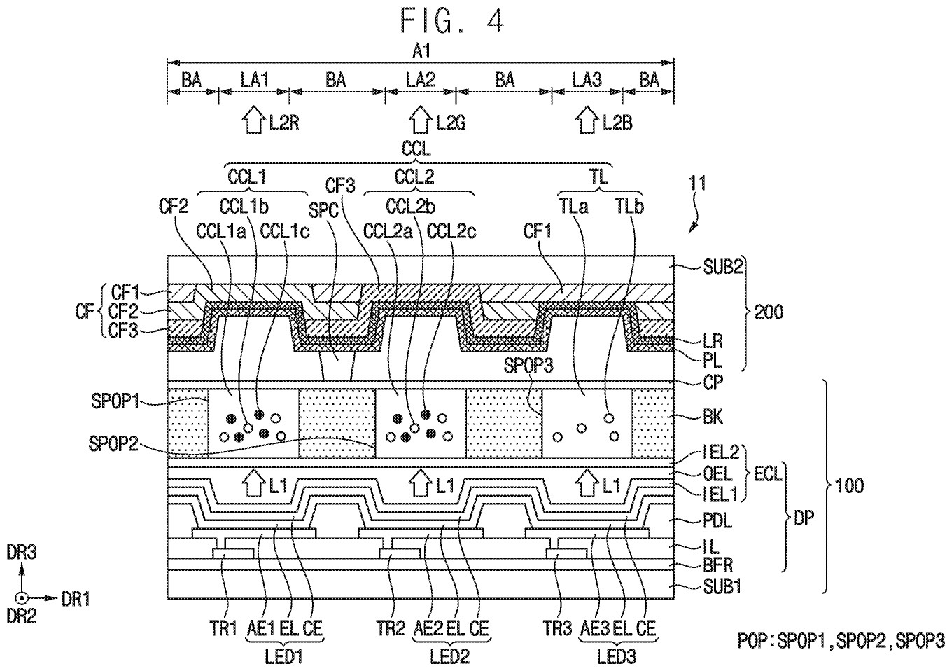

FIG. 4 is a schematic cross-sectional view illustrating another example of FIG. 3. Portions of a display devices 11 described with reference to FIG. 4 overlapping those of the display device 10 described with reference to FIG. 3 may be omitted or simplified.

Referring to FIGS. 1, 2 and 4, the display device 11 may include the first substrate 100 and the second substrate 200. The second substrate 200 may face the first substrate 100. The sealing member SLM may be disposed between the first substrate 100 and the second substrate 200. The sealing member SLM may couple the first substrate 100 and the second substrate 200 together.

The display device 10 may include the first area A1 where an image is displayed, the second area A2 surrounding the first area A1, and the third area A3 surrounding the second area A2. For example, the first area A1 may be a display area, and the second area A2 and the third area A3 may be non-display areas.

The first substrate 100 may include a display structure and may be referred to as a display substrate. The display structure may be disposed on the first area A1 of the first substrate 100.

The second substrate 200 may include a color conversion layer and may be referred to as a color conversion substrate. The color conversion layer may be disposed in the first area A1. The second substrate 200 may further include a color filter layer that transmits light of a specific color.

A filling layer may be disposed between the first substrate 100 and the second substrate 200. The filling layer may act as a buffer against external pressure applied to the display device 11. The filling layer may maintain a gap between the first substrate 100 and the second substrate 200. However, the disclosure is not limited thereto.

In an embodiment, the first substrate 100 may include the first base substrate SUB1 and the display structure DP. The display structure DP may be disposed on the first base substrate SUB1 and may overlap the first area A1. The display structure DP may include the buffer layer BFR, the first, second, and third driving elements TR1, TR2, and TR3, the insulating layer IL, the pixel defining layer PDL, the first, second,, and third light emitting diodes LED1, LED2, and LED3, the encapsulation layer ECL, the bank portion BK, the color conversion layer CCL, and the capping layer CP.

The buffer layer BFR may be disposed on the first base substrate SUB1, and the first, second, and third driving elements TR1, TR2, and TR3 and the insulating layer IL may be disposed on the buffer layer BFR, the pixel defining layer PDL and the first, second, and third light emitting diodes LED1, LED2, and LED3 may be disposed on the insulating layer IL, and the encapsulation layer ECL may be disposed on the first, second, and third light emitting diodes LED1, LED2, and LED3.

In an embodiment, the bank portion BK may be disposed on the encapsulation layer ECL. For example, the bank portion BK may be disposed between the first base substrate SUB1 and the second base substrate SUB2. The bank portion BK may overlap the first area A1 and the second area A2. The bank portion BK may define openings.

The openings may overlap the first area A1 and the second area A2. For example, the openings of the bank portion BK may include the pixel openings POP overlapping the first area A1. The pixel openings POP may include the first, second, and third sub-pixel openings SPOP1, SPOP2, and SPOP3.

The bank portion BK may include an organic material. In an embodiment, the bank portion BK may further include a light blocking material.

In an embodiment, the color conversion layer CCL may be disposed on the encapsulation layer ECL and may overlap the first area A1. The color conversion layer CCL may be disposed in the pixel openings POP. The color conversion layer CCL may include color conversion portions spaced apart from each other on the upper surface of the encapsulation layer ECL. In an embodiment, the color conversion layer CCL may include the first color conversion portion CCL1, the second color conversion portion CCL2, and the transmission portion TL. The first color conversion portion CCL1, the second color conversion portion CCL2, and the transmission portion TL may be disposed in the first area A1 under the color filter layer CF and may overlap the three light emitting areas LA1, LA2, and LA3, respectively. For example, the first color conversion portion CCL1, the second color conversion portion CCL2, and the transmission portion TL may be disposed in the first, second, and third sub-pixel openings SPOP1, SPOP2, and SPOP3 of the bank portion BK, respectively.

The first color conversion portion CCL1 may overlap the first light emitting area LA1. The first color conversion portion CCL1 may convert the incident light L1 into the first transmitted light L2R having the red color. For example, the first color conversion portion

CCL1 may include the resin portion CCL1a, the scattering material CCL1b, and the wavelength conversion particle CCL1c. The wavelength conversion particle CCL1c may include quantum dots. The quantum dots may be defined as a semiconductor material having nanocrystals.

The second color conversion portion CCL2 may overlap the second light emitting area LA2. The second color conversion portion CCL2 may convert the incident light L1 into the second transmitted light L2G having the green color. For example, the second color conversion portion CCL2 may include the resin portion CCL2a, the scattering material CCL2b, and the wavelength conversion particle CCL2c.

The transmission portion (or transmission part) TL may overlap the third light emitting area LA3. The transmission portion TL may transmit the incident light L1 to emit the third transmitted light L2B. For example, the transmission portion TL may include the resin portion TLa and the scattering material TLb.

However, the disclosure is not limited thereto, and the transmission portion TL may convert the incident light L1 into the third transmitted light L2B having the blue color. The transmission portion TL may further include wavelength conversion particles including quantum dots that absorb the incident light L1 and emit blue light.

The capping layer CP may be disposed on the bank portion BK and the color conversion layer CCL. The capping layer CP may protect the color conversion layer CCL from, e.g., oxygen, moisture, foreign substances, and the like. For example, the capping layer CP may cover the bank portion BK and the color conversion layer CCL.

In an embodiment, the second substrate 200 may include the second base substrate SUB2, the color filter layer CF, the low refractive index layer LR, the protective layer PL, and a spacer SPC.

The second base substrate SUB2 may face the first base substrate SUB1. The color filter layer CF may be disposed under the second base substrate SUB2, and the low refractive index layer LR may be disposed under the color filter layer CF. The protective layer PL may be disposed under the low refractive index layer LR.

In an embodiment, the spacer SPC may be disposed under the protective layer PL. The spacer SPC may be disposed in the light blocking area BA. FIG. 4 illustrates that a spacer SPC is disposed in the light blocking area BA, but the disclosure is not limited thereto. For another example, spacers SPC may be formed, and positions where the spacers SPC are formed may be variously determined in the light blocking area BA.

A lower surface of the spacer SPC may contact the capping layer CP. Accordingly, the spacer SPC may maintain a gap between the first substrate 100 and the second substrate 200.

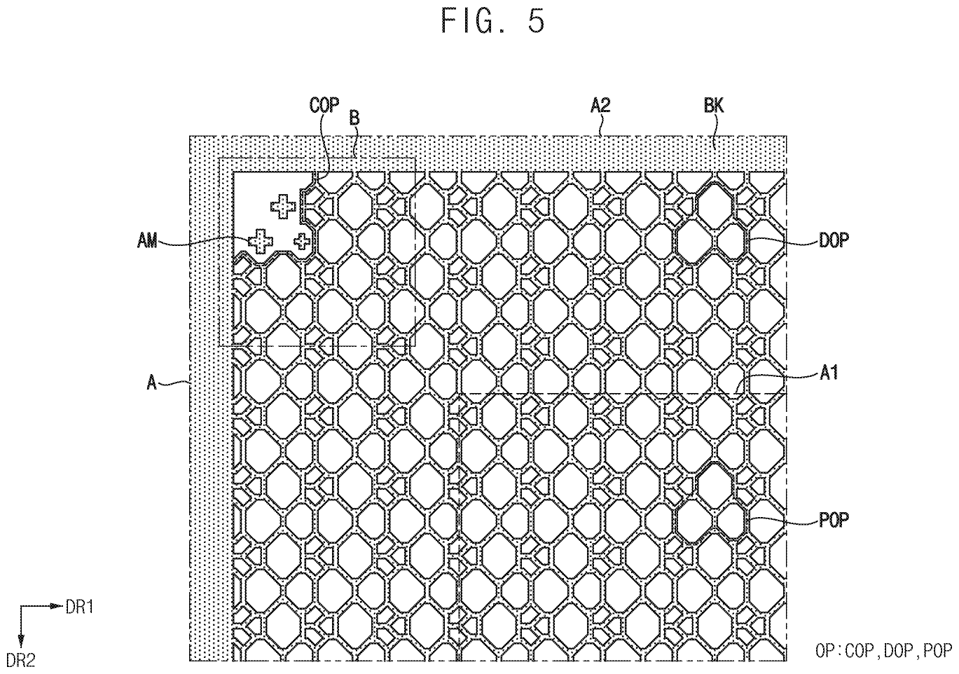

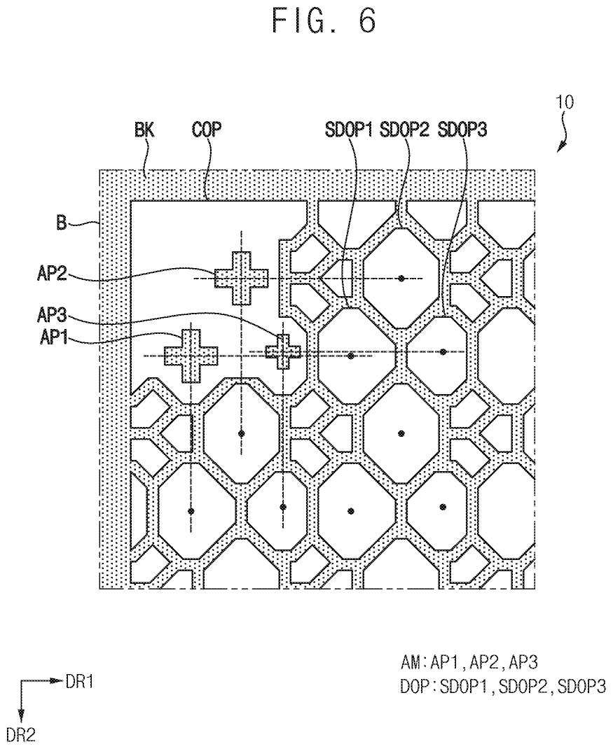

FIG. 5 is a schematic enlarged plan view of area A of FIG. 1. FIG. 6 is a schematic enlarged plan view of area B of FIG. 5.

Referring to FIGS. 1, 5, and 6, the display device 10 may further include an alignment mark AM. The alignment mark AM may indicate a starting point during an inkjet process. For example, the inkjet process may be started from the opening where the alignment mark AM is positioned.

In an embodiment, the bank portion BK may overlap the first and second areas A1 and A2. The bank portion BK may define openings OP overlapping the first and second areas A1 and A2. The openings OP may include a corner opening COP, dummy openings DOP, and the pixel openings POP.

The pixel openings POP may be entirely defined in the first area A1. The pixel openings POP may be arranged in the first and second directions DR1 and DR2. Each of the pixel openings POP may include first, second, and third sub-pixel openings SPOP1, SPOP2, and SPOP3 adjacent to each other. The color conversion portions and the transmission portion (e.g., the first color conversion portion CCL1, the second color conversion portion CCL2, and the transmission portion TL of FIGS. 3 and 4) may be disposed in the first, second, and third sub-pixel openings SPOP1, SPOP2, and SPOP3, respectively.

In an embodiment, the dummy openings DOP and the corner openings COP may be entirely defined in the second area A2.

In an embodiment, the corner opening COP may be defined at at least one corner of the second area A2. The inkjet process may be started at a corner where the corner opening COP is defined. FIG. 5 illustrates that the corner opening COP is defined at one corner, but the disclosure is not limited thereto. In another embodiment, the corner opening COP may be defined at all corners. In another embodiment, the corner opening COP is not limited to the corner of the second area A2 and may be defined in a part of the second area A2 including the corner.

The dummy openings DOP may be defined in the second area A2 excluding the corner opening COP. Each of the dummy openings DOP may include first, second, and third sub-dummy openings SDOP1, SDOP2, and SDOP3 adjacent to each other. The color conversion portions and the transmission portion (e.g., the first color conversion portion CCL1, the second color conversion portion CCL2, and the transmission portion TL of FIGS. 3 and 4) may be disposed in the first, second, and third sub-dummy openings SDOP1, SDOP2, and SDOP3, respectively. However, the disclosure is not limited thereto, and the color conversion portions and transmission portion may not be disposed in the first, second, and third sub-dummy openings SDOP1, SDOP2, and SDOP3, respectively.

The first sub-dummy opening SDOP1 and the third sub-dummy opening SDOP3 may be adjacent to each other in the first direction DR1. The second sub-dummy opening SDOP2 may be adjacent to a portion between the first sub-dummy opening SDOP1 and the third sub-dummy opening SDOP3 in the second direction DR2. For example, a center part of the first sub-dummy opening SDOP1, a center part of the second sub-dummy opening SDOP2, and a center part of the third sub-dummy opening SDOP3 may form a triangular shape. However, the disclosure is not limited thereto.

Shapes of the dummy openings DOP may be the same as shapes of the pixel openings POP. For example, the shapes of the first, second, and third sub-dummy openings SDOP1, SDOP2, and SDOP3 may be the same as the shapes of the first, second, and third sub-pixel openings SPOP1, SPOP2, and SPOP3, respectively. Each of the first, second, and third sub-dummy openings SDOP1, SDOP2, and SDOP3 may have a polygonal shape. For example, each of the shapes of the first, second, and third sub-dummy openings SDOP1, SDOP2, and SDOP3 may have an octagonal shape. However, the disclosure is not limited thereto.

In an embodiment, the shape of the corner opening COP may be different from the shape of each of the first, second, and third sub-dummy openings SDOP1, SDOP2, and SDOP3. The area of the corner opening COP may be larger than the area of each of the first, second, and third sub-dummy openings SDOP1, SDOP2, and SDOP3 in a plan view.

In an embodiment, the alignment mark AM may be disposed in the corner opening COP. The alignment mark AM may be integral with the bank portion BK. For example, the alignment mark AM may include the same material as the bank portion BK.

In an embodiment, a center part of the alignment mark AM may be positioned on the same line in the first direction DR1 as a center part of an opening adjacent to the corner opening COP among the plurality of openings OP in the first direction DR1. The center part of the alignment mark AM may be positioned on the same line in the second direction DR2 as a center part of an opening adjacent to the corner opening COP among the plurality of openings OP in the second direction DR2.

For example, the alignment mark AM may include first, second, and third alignment patterns AP1, AP2, and AP3 adjacent to each other. Each of the first, second, and third alignment patterns AP1, AP2, and AP3 may have a cross shape. However, the disclosure is not limited thereto.

The first alignment pattern AP1 may overlap the first sub-dummy openings SDOP1 in the first and second directions DR1 and DR2. Specifically, a center part of the first alignment pattern AP1 may be positioned on the same line in the first direction DR1 as a center part of the first sub-dummy opening SDOP1 adjacent the first direction DR1. The center part of the first alignment pattern AP1 may be positioned on the same line in the second direction DR2 as a center part of the first sub-dummy opening SDOP1 adjacent in the second direction DR2.

The second alignment pattern AP2 may overlap the second sub-dummy openings SDOP2 in the first and second directions DR1 and DR2. Specifically, a center part of the second alignment pattern AP2 may be positioned on the same line in the first direction DR1 as a center part of the second sub-dummy opening SDOP2 adjacent in the first direction DR1. The center part of the second alignment pattern AP2 may be positioned on the same line in the second direction DR2 as a center part of the second sub-dummy opening SDOP2 adjacent in the second direction DR2.

The third alignment pattern AP3 may overlap the third sub-dummy openings SDOP3 in the first and second directions DR1 and DR2. Specifically, a center part of the third alignment pattern AP3 may be positioned on the same line in the first direction DR1 as a center part of the third sub-dummy opening SDOP3 adjacent in the first direction DR1. The center part of the third alignment pattern AP3 may be positioned on the same line in the second direction DR2 as a center part of the third sub-dummy opening SDOP3 adjacent in the second direction DR2.

In an embodiment, a global mark may be further disposed in the third area A3. The global mark may be a mark for aligning members as a whole when manufacturing the display device 10. The shape of the global mark may be a cross shape. Accordingly, the shape of the global mark and the shape of each of the first, second, and third alignment patterns AP1, AP2, and AP3 may be substantially the same as each other. However, the disclosure is not limited thereto, and in another embodiment, the global mark may be disposed on a mother substrate for manufacturing the display device 10 and may be removed during manufacturing of the display device 10.

In an embodiment, the display device 10 may further include the alignment mark AM disposed in the corner opening COP. The alignment mark AM may indicate a starting point in the inkjet process. Accordingly, the inkjet process may be started from the position where the alignment mark AM is disposed. When the color conversion layer is formed by an inkjet apparatus, the position of the inkjet apparatus may be corrected using the alignment mark AM whenever ink is printed on the openings of the bank portion BK. Accordingly, defects of the display device 10 due to misplacement of the ink during the inkjet process may be prevented and reliability of the display device 10 may be improved.

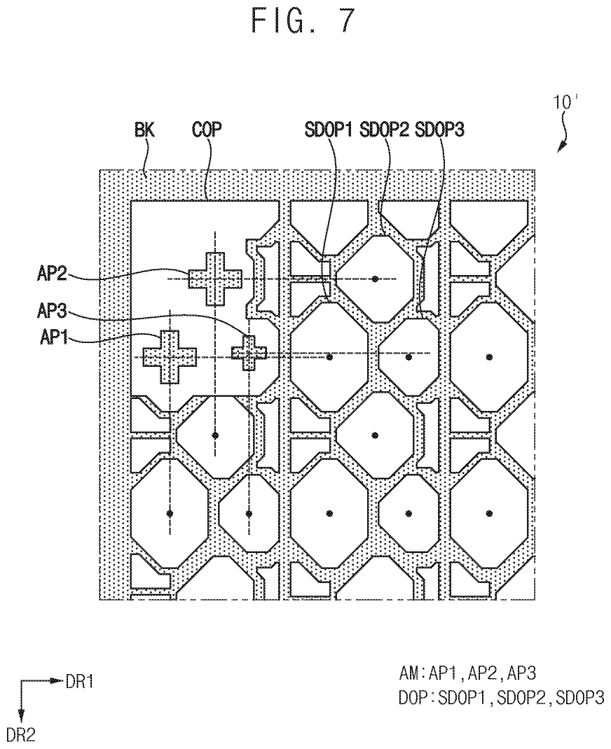

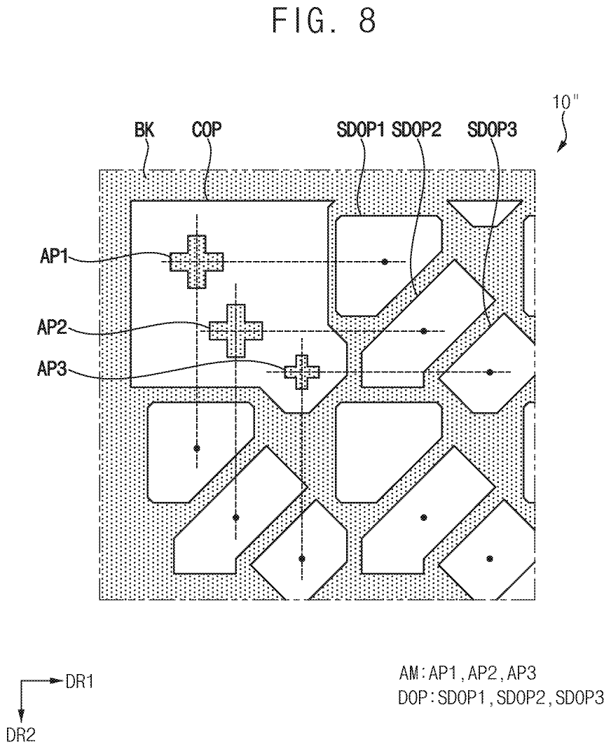

FIGS. 7 and 8 are schematic plan views illustrating other examples of FIG. 6.

A display device 10′ described with reference to FIG. 7 and a display device 10″ described with reference to FIG. 8 may be the same as the display device 10 described with reference to FIG. 6 except for the shape of each of the corner openings COP, the dummy openings DOP, and the pixel openings POP. Accordingly, redundant descriptions may be omitted or simplified.

Referring to FIG. 7, the first sub-dummy opening SDOP1 and the third sub-dummy opening SDOP3 may be adjacent to each other in the first direction DR1. The second sub-dummy opening SDOP2 may be adjacent to a portion between the first sub-dummy opening SDOP1 and the third sub-dummy opening SDOP3 in the second direction DR2. For example, the center part of the first sub-dummy opening SDOP1, the center part of the second sub-dummy opening SDOP2, and the center part of the third sub-dummy opening SDOP3 may form a triangular shape. However, the disclosure is not limited thereto.

Each of the shapes of the first, second, and third sub-dummy openings SDOP1, SDOP2, and SDOP3 may have a polygonal shape. For example, each of the shapes of the first, second, and third sub-dummy openings SDOP1, SDOP2, and SDOP3 may have an octagonal shape. However, the disclosure is not limited thereto. The shapes of the first, second, and third sub-dummy openings SDOP1, SDOP2, and SDOP3 of FIG. 7 may be slightly different from the shapes of the first, second, and third sub-dummy openings SDOP1, SDOP2, and SDOP3 of FIG. 6. For example, the shapes of the first, second, and third sub-dummy openings SDOP1, SDOP2, and SDOP3 may be variously changed.

Referring to FIG. 8, the first, second, and third sub-dummy openings SDOP1, SDOP2, and SDOP3 may be sequentially arranged in a diagonal direction crossing the first and second directions DR1 and DR2. For example, the second sub-dummy opening SDOP2 may be adjacent to the first sub-dummy opening SDOP1 in the diagonal direction, and the third sub-dummy opening SDOP3 may be adjacent to the second sub-dummy opening SDOP2 in the diagonal direction.

Each of the shapes of the first, second, and third sub-dummy openings SDOP1, SDOP2, and SDOP3 may have a polygonal shape. For example, the first sub-dummy opening SDOP1 may have a pentagonal shape. The second sub-dummy opening SDOP2 may have a hexagonal shape. The third sub-dummy opening SDOP3 may have a hexagonal shape. However, the disclosure is not limited thereto. For example, the first, second, and third sub-dummy openings SDOP1, SDOP2, and SDOP3 may all have different shapes.

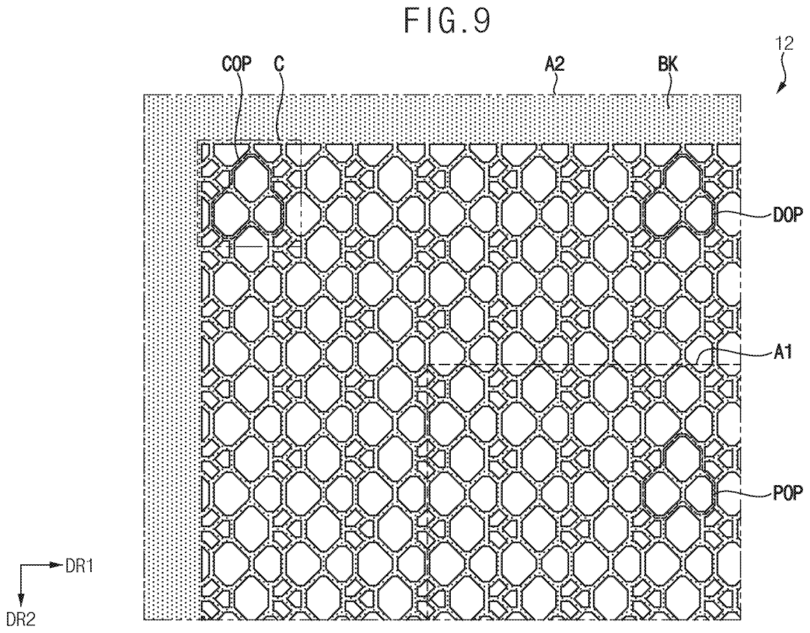

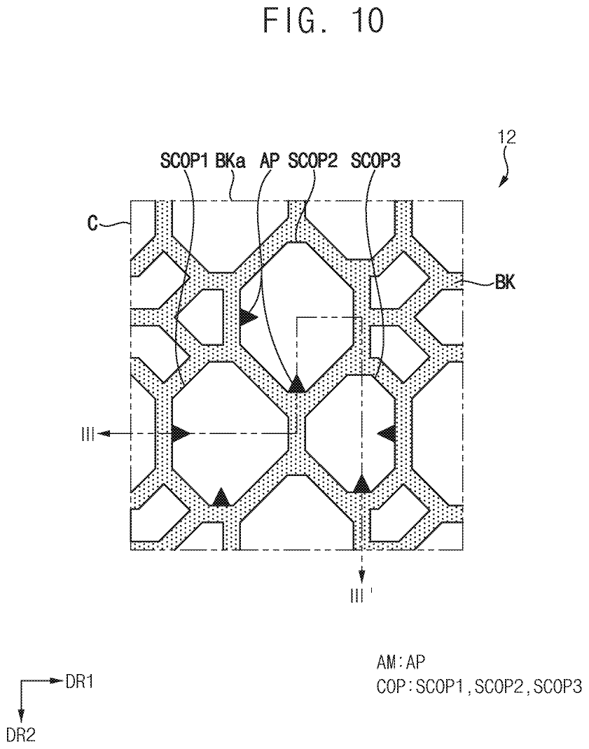

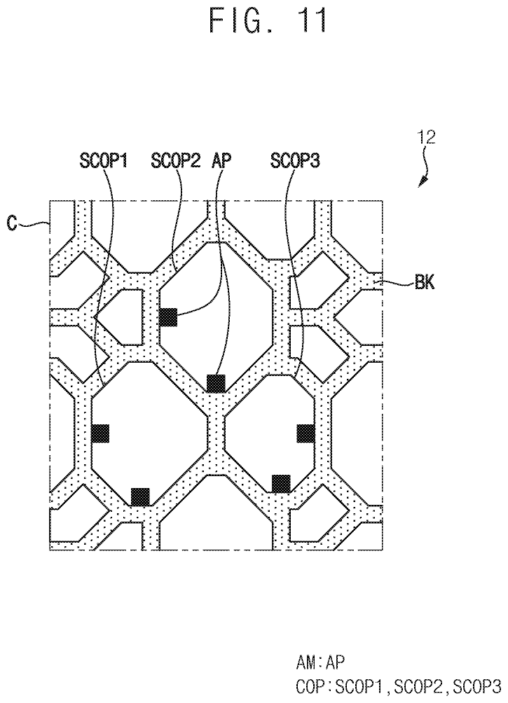

FIG. 9 is a schematic plan view illustrating another example of FIG. 5. FIG. 10 is a schematic enlarged plan view of area C of FIG. 9. FIG. 11 is a schematic plan view illustrating another example of FIG. 10.

A display device 12 described with reference to FIGS. 9, 10, and 11 may be the same as the display device 10 described with reference to FIGS. 1, 2, 3, 5, and 6 except for the alignment marks AM. Accordingly, redundant descriptions may be omitted or simplified.

Referring to FIGS. 9, 10, and 11, the display device 12 may include a first base substrate, a display structure, a second base substrate, the bank portion BK, a color conversion layer, and the alignment mark AM. The display device 12 may further include a sealing member, a color filter layer, a low refractive index layer, a protective layer, and a capping layer.

The display structure may be disposed on the first base substrate, and the second base substrate may face the first base substrate. The second base substrate SUB2 may include the first area A1, the second area A2, and a third area. The first area A1 may overlap the display structure, the second area A2 may surround the first area A1, and the third area may surround the second area A2.

In an embodiment, the bank portion BK may be disposed between the first base substrate and the second base substrate. The bank portion BK may overlap the first and second areas A1 and A2. The bank portion BK may define the openings OP overlapping the first and second areas A1 and A2. The color conversion layer CCL may be disposed in the openings OP. The openings OP may include the corner opening COP, the dummy openings DOP, and the pixel openings POP.

The pixel openings POP may be entirely defined in the first area A1. The pixel openings POP may be arranged in the first and second directions DR1 and DR2. Each of the pixel openings POP may include the first, second, and third sub-pixel openings SPOP1, SPOP2, and SPOP3 adjacent to each other. The color conversion portions and the transmission portion (e.g., the first color conversion portion CCL1, the second color conversion portion CCL2, and the transmission portion TL of FIGS. 3 and 4) may be disposed in the first, second, and third sub-pixel openings SPOP1, SPOP2, and SPOP3, respectively.

In an embodiment, the dummy openings DOP and the corner opening COP may be defined in the second area A2.

In an embodiment, the corner opening COP may be defined at at least one corner of the second area A2. The inkjet process may be started at a corner where the corner opening COP is defined. FIG. 9 illustrates that the corner opening COP is defined at one corner, but the disclosure is not limited thereto. For another example, the corner opening COP may be defined at all corners. As another example, the corner opening COP is not limited to the corner of the second area A2 and may be defined in a part of the second area A2 including the corner.

In an embodiment, the corner opening COP may include first, second, and third sub-corner openings SCOP1, SCOP2, and SCOP3 adjacent to each other.

For example, the first sub-corner opening SCOP1 and the third sub-corner opening SCOP3 may be adjacent to each other in the first direction DR1. The second sub-corner opening SCOP2 may be adjacent to a portion between the first sub-corner opening SCOP1 and the third sub-corner opening SCOP3 in the second direction DR2. For example, a center part of the first sub-corner opening SCOP1, a center part of the second sub-corner opening SCOP2, and a center part of the third sub-corner opening SCOP3 may form a triangular shape. However, the disclosure is not limited thereto.

The dummy openings DOP may be defined in the second area A2 excluding the corner opening COP. Each of the dummy openings DOP may include the first, second, and third sub-dummy openings SDOP1, SDOP2, and SDOP3 adjacent to each other. The color conversion portions and the transmission portion (e.g., the first color conversion portion CCL1, the second color conversion portion CCL2, and the transmission portion TL of FIGS. 3 and 4) may be disposed in the first, second, and third sub-dummy openings SDOP1, SDOP2, and SDOP3, respectively. However, the disclosure is not limited thereto, and the color conversion portions and the transmission portion may not be disposed in the first, second, and third sub-dummy openings SDOP1, SDOP2, and SDOP3, respectively.

The dummy openings DOP and the pixel openings POP may have a same shape. For example, the shapes of the first, second, and third sub-dummy openings SDOP1, SDOP2, and SDOP3 may be the same as the shapes of the first, second, and third sub-pixel openings SPOP1, SPOP2, and SPOP3, respectively. Each of the first, second, and third sub-dummy openings SDOP1, SDOP2, and SDOP3 may have a polygonal shape. For example, each of the shapes of the first, second, and third sub-dummy openings SDOP1, SDOP2, and SDOP3 may have an octagonal shape. However, the disclosure is not limited thereto.

In an embodiment, the corner opening COP may have the same shape as each of the dummy openings DOP. For example, the shapes of the first, second, and third sub-corner openings SCOP1, SCOP2, and SCOP3 may be the same as the shapes of the first, second, and third sub-dummy openings SDOP1, SDOP2, and SDOP3, respectively.

In an embodiment, the alignment mark AM may be disposed in the corner opening COP. The alignment mark AM may indicate a starting point during the inkjet process. For example, the inkjet process may be started from the opening where the alignment mark AM is positioned. However, the disclosure is not limited thereto, and the alignment mark AM may be used in various ways depending on the part requiring marking during the inkjet process.

The alignment mark AM may be integral with the bank portion BK. For example, the alignment mark AM may include the same material as the bank portion BK.

In an embodiment, the alignment mark AM may protrude in a direction from the bank portion BK to the corner opening COP. For example, the alignment mark AM may protrude from a side surface BKa of the bank portion BK. However, the disclosure is not limited thereto, and in another embodiment, the alignment mark AM may be formed in an intaglio pattern instead of an embossed pattern. For example, the alignment mark AM may have a concave shape without protruding.

In an embodiment, the alignment mark AM may include at least one alignment pattern AP. The alignment pattern AP may be disposed in each of the first, second, and third sub-corner openings SCOP1, SCOP2, and SCOP3. For example, the alignment pattern AP may be formed in plurality. FIG. 10 illustrates that two alignment patterns AP may be disposed in each of the first, second, and third sub-corner openings SCOP1, SCOP2, and SCOP3. However, the disclosure is not limited thereto, and in another embodiment, one or three or more alignment patterns AP may be disposed in each of the first, second, and third sub-corner openings SCOP1, SCOP2, and SCOP3.

The shape of the alignment pattern AP may be a triangle (see FIG. 10) or a rectangle (see FIG. 11). However, the disclosure is not limited thereto, and in another embodiment, the shape of the alignment pattern AP may be a polygon, and the alignment patterns AP may have different shapes.

In an embodiment, the display device 12 may further include the alignment mark AM disposed in the corner openings COP. The alignment mark AM may indicate a starting point in the inkjet process. Accordingly, the inkjet process may be started from the position where the alignment mark AM is disposed. When the color conversion layer is formed by the inkjet apparatus, the position of the inkjet apparatus may be corrected using the alignment mark AM whenever ink is printed on openings of the bank portion BK. Accordingly, defects of the display device 12 due to misplacement of the ink during the inkjet process may be prevented and reliability of the display device 12 may be improved.

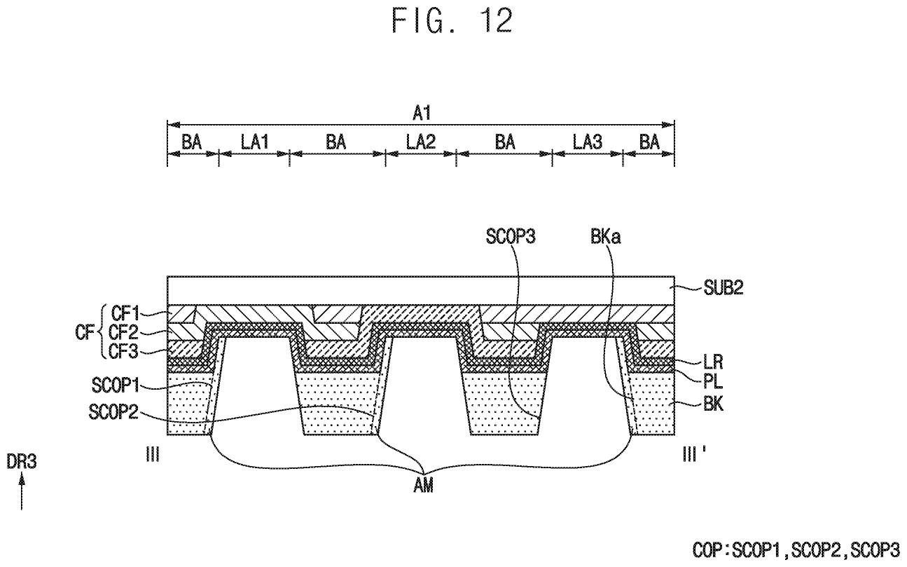

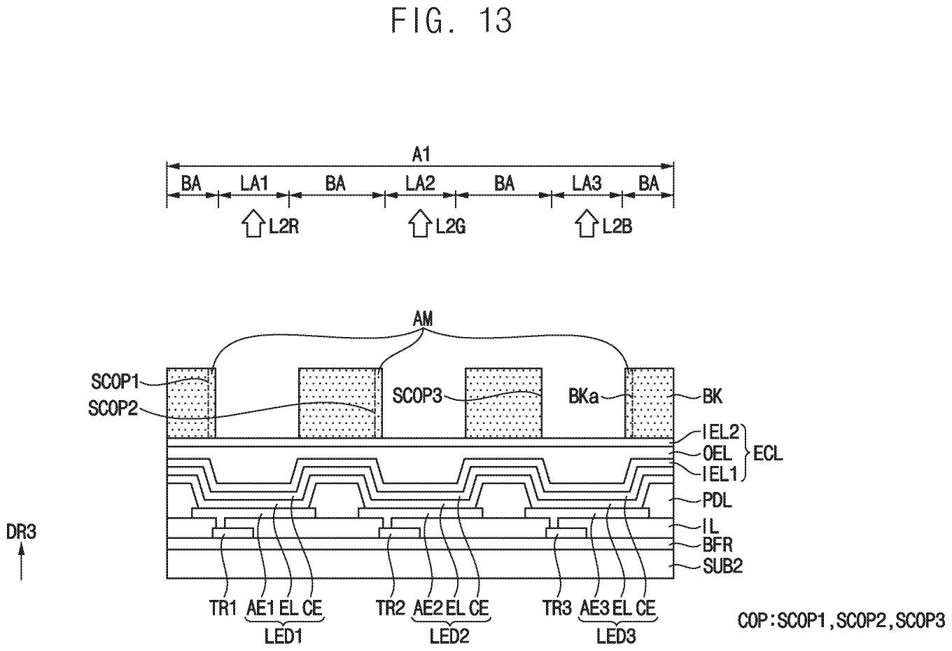

FIG. 12 is a schematic cross-sectional view taken along line III-III′ of FIG. 10.

For example, FIG. 12 may be a view illustrating only the second base substrate SUB2, the color filter layer CF, the low refractive index layer LR, the protective layer PL, the bank portion BK, and the alignment mark AM of the display device.

Referring to FIG. 12, the color filter layer CF may be disposed under the second base substrate SUB2, the low refractive index layer LR and the protective layer PL may be disposed under the color filter layer CF, and the bank portion BK and the alignment mark AM may be disposed under the protective layer PL.

In an embodiment, the alignment mark AM may protrude from the bank portion BK under the protective layer PL. For example, the alignment mark AM may protrude from the side surface BKa of the bank portion BK.

FIG. 13 is a schematic cross-sectional view illustrating another example of FIG. 12.

For example, FIG. 13 may be a view illustrating only the first base substrate SUB1, the buffer layer BFR, the first, second, and third driving elements TR1, TR2, and TR3, the insulating layer IL, the first, second, and third light emitting diodes LED1, LED2, and LED3, the pixel defining layer PDL, the encapsulation layer ECL, the bank portion BK, and the alignment mark AM.

Referring to FIG. 13, the buffer layer BFR may be disposed on the first base substrate SUB1, the first, second, and third driving elements TR1, TR2, and TR3 and the insulating layer IL may be disposed on the buffer layer BFR, and the pixel defining layer PDL and the first, second, and third light emitting diodes LED1, LED2, and LED3 may be disposed on the first, second, and third driving elements TR1, TR2, and TR3 and the insulating layer IL. The encapsulation layer ECL may be disposed on the pixel defining layer PDL and the first, second, and third light emitting diodes LED1, LED2, and LED3. The bank portion BK and the alignment mark AM may be disposed on the encapsulation layer ECL.

In an embodiment, the alignment mark AM may protrude from the bank portion BK on the encapsulation layer ECL. For example, the alignment mark AM may protrude from the side surface BKa of the bank portion BK.

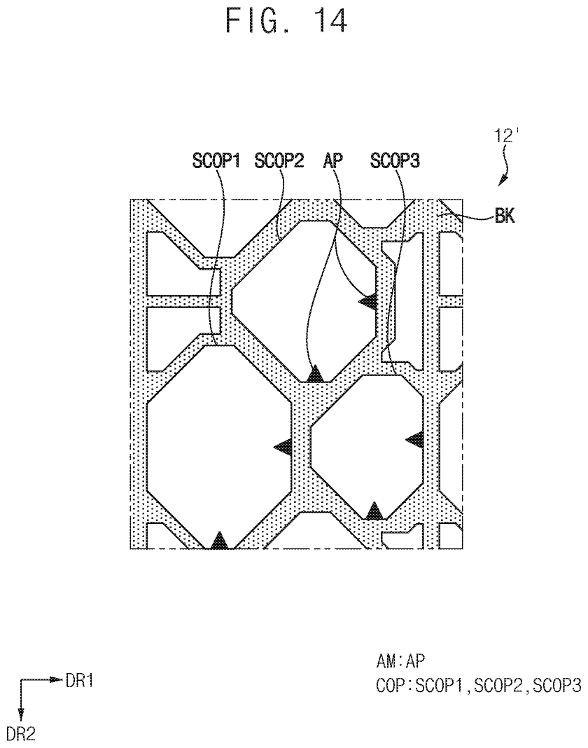

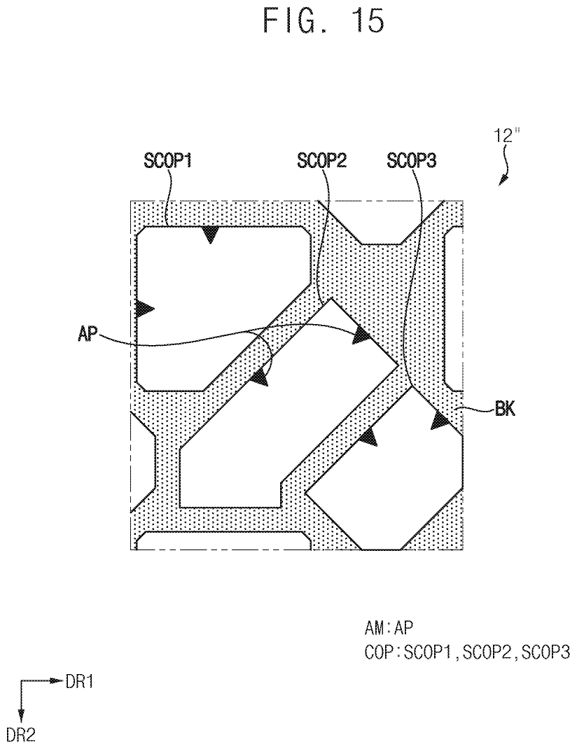

FIGS. 14 and 15 are schematic plan views illustrating other examples of FIG. 10.

A display device 12′ described with reference to FIG. 14 and a display device 12″ described with reference to FIG. 15 may be the same as the display device 12 described with reference to FIG. 10 except for the shape of each of the corner opening COP, the dummy openings DOP, and the pixel openings POP. Accordingly, redundant descriptions may be omitted or simplified.

Referring to FIG. 14, the first sub-corner opening SCOP1 and the third sub-corner opening SCOP3 may be adjacent to each other in the first direction DR1. The second sub-corner opening SCOP2 may be adjacent to a portion between the first sub-corner opening SCOP1 and the third sub-corner opening SCOP3 in the second direction DR2. For example, the center part of the first sub-corner opening SCOP1, the center part of the second sub-corner opening SCOP2, and the center part of the third sub-corner opening SCOP3 may form a triangular shape. However, the disclosure is not limited thereto.

Each of the shapes of the first, second, and third sub-corner openings SCOP1, SCOP2, and SCOP3 may have a polygonal shape. For example, each of the shapes of the first, second, and third sub-corner openings SCOP1, SCOP2, and SCOP3 may have an octagonal shape. However, the disclosure is not limited thereto. The shapes of the first, second, and third sub-corner openings SCOP1, SCOP2, and SCOP3 of FIG. 14 may be slightly different from the shapes of the first, second, and third sub-corner openings SCOP1, SCOP2, and SCOP3 of FIG. 10. For example, the shapes of the first, second, and third sub-corner openings SCOP1, SCOP2, and SCOP3 may be variously changed.

In an embodiment, the alignment patterns AP may be respectively disposed on two side surfaces of each of the first, second, and third sub-corner openings SCOP1, SCOP2, and SCOP3. However, the disclosure is not limited thereto.

Referring to FIG. 15, the first, second, and third sub-corner openings SCOP1, SCOP2, and SCOP3 may be sequentially arranged in a diagonal direction crossing the first direction DR1 and the second direction DR2. For example, the second sub-corner opening SCOP2 may be adjacent to the first sub-corner opening SCOP1 in the diagonal direction, and the third sub-corner opening SCOP3 may be adjacent to the second sub-corner opening SCOP2 in the diagonal direction.

Each of the shapes of the first, second, and third sub-corner openings SCOP1, SCOP2, and SCOP3 may have a polygonal shape. For example, the first sub-corner opening SCOP1 may have a pentagonal shape. The second sub-corner opening SCOP2 may have a hexagonal shape. The third sub-corner opening SCOP3 may have a hexagonal shape. However, the disclosure is not limited thereto. For example, the first, second, and third sub-corner openings SCOP1, SCOP2, and SCOP3 may all have different shapes.

In an embodiment, the alignment patterns AP may be respectively disposed on two side surfaces of each of the first, second, and third sub-corner openings SCOP1, SCOP2, and SCOP3. However, the disclosure is not limited thereto.

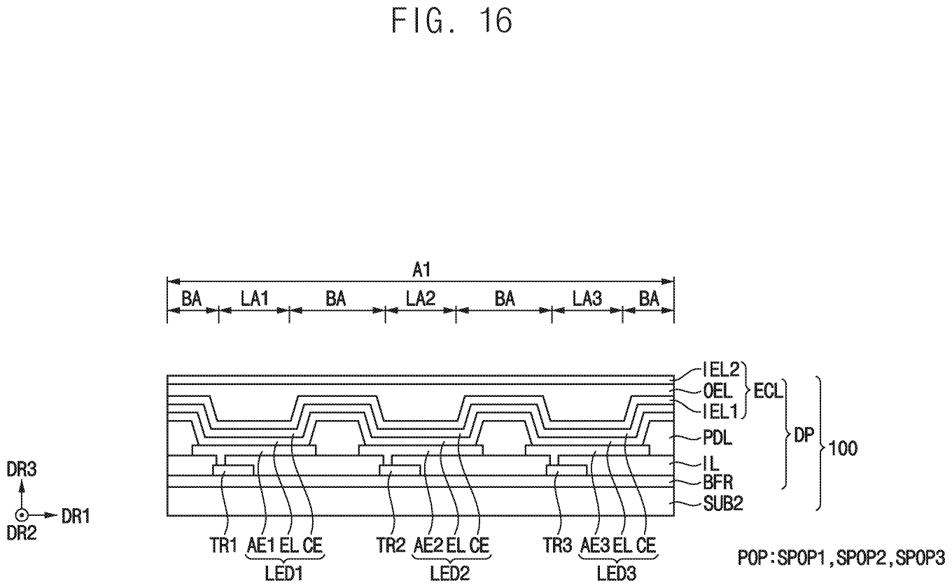

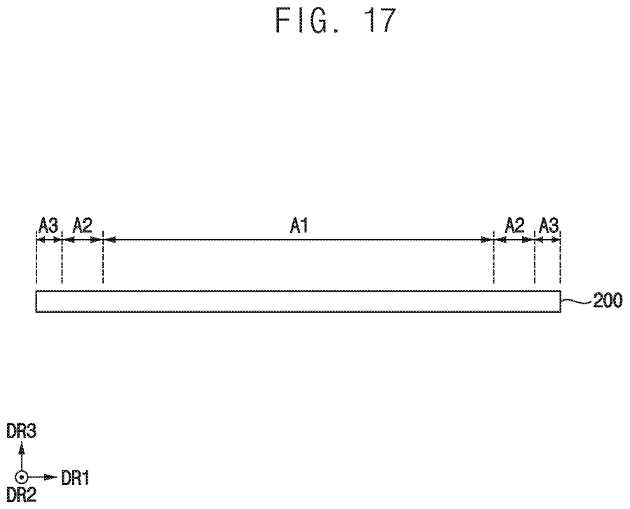

FIGS. 16, 17, 18, 19, 20, 21, 22, and 23 are schematic views illustrating a method of manufacturing a display device according to an embodiment.

For example, the method of manufacturing the display device described with reference to FIGS. 16, 17, 18, 19, 20, 21, 22, and 23 may be the method of manufacturing the display device 10 described with reference to FIGS. 1, 2, and 3. Accordingly, redundant descriptions may be omitted or simplified.

Referring to FIG. 16, the display structure DP may be formed on the first base substrate SUB1. Thus, the first substrate 100 including the first base substrate SUB1 and the display structure DP may be formed.

Referring to FIGS. 17, 18, 19, 20, 21, and 22, the second substrate 200 may be formed.

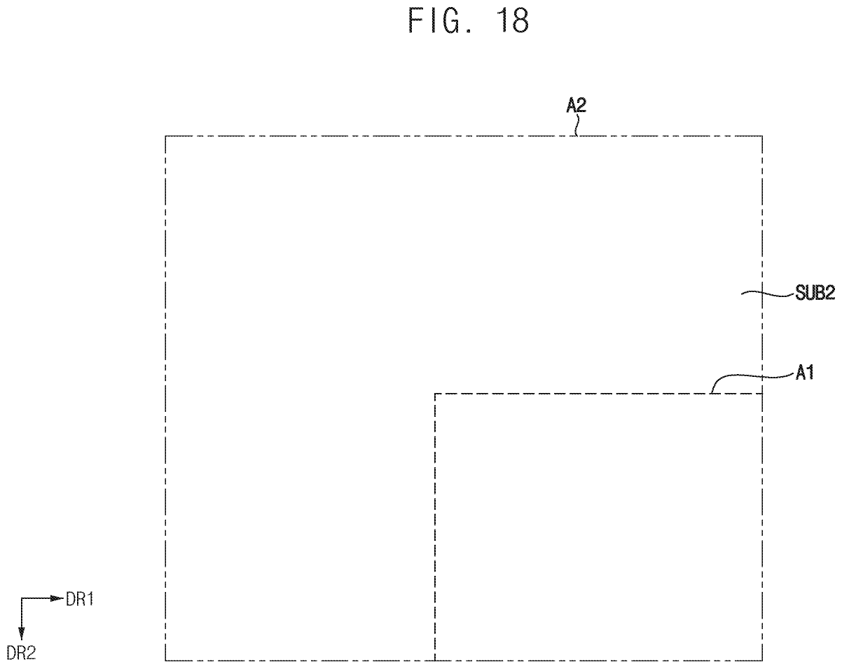

FIGS. 18, 19, 20, and 21 may be schematic enlarged plan views of a part of FIG. 17.

Referring to FIGS. 17, 18, and 22, the second base substrate SUB2 including the first area A1, the second area A2, and the third area A3 may be formed. The color filter layer CF may be formed on the second base substrate SUB2, the low refractive index layer LR may be formed on the color filter layer CF, and the protective layer PL may be formed on the low refractive index layer LR.

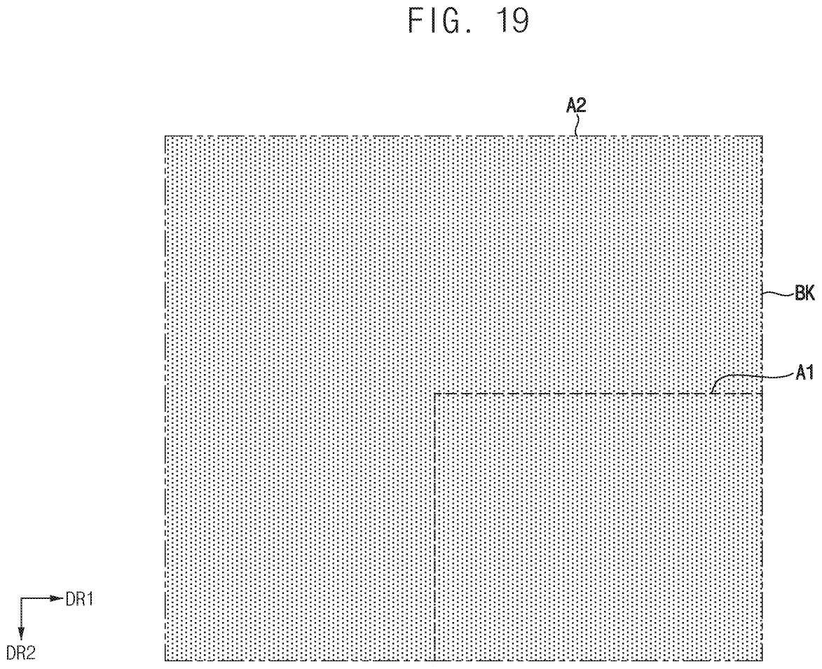

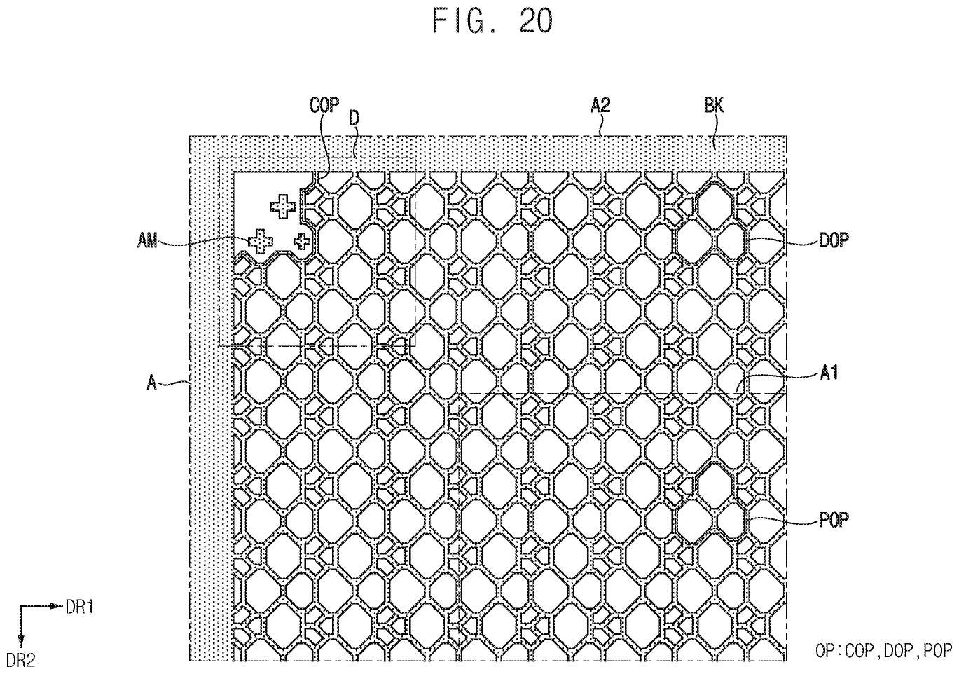

Further referring to FIG. 19, the bank portion BK may be formed on the protective layer PL. The bank portion BK may be formed to overlap the first and second areas A1 and A2.

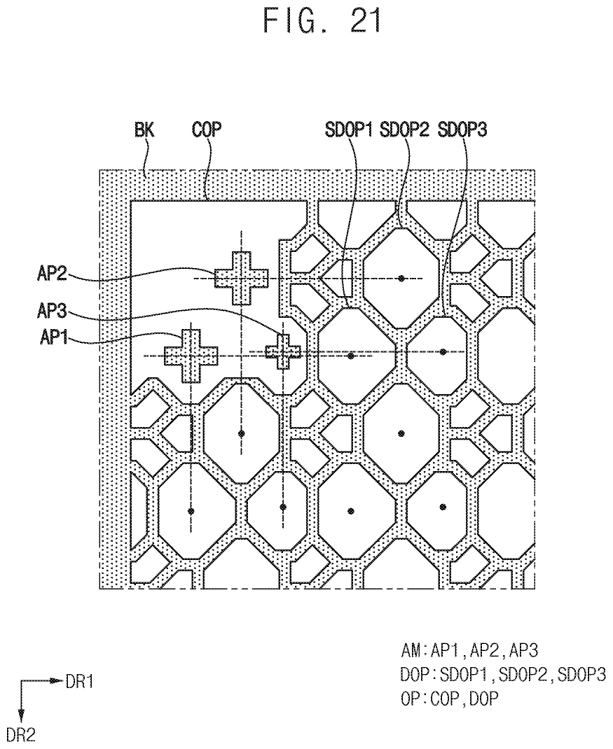

Further referring to FIG. 20, the openings OP overlapping the first and second areas A1 and A2 may be formed in the bank portion BK. The openings OP may include the corner opening COP, the dummy openings DOP, and the pixel openings POP.

The pixel openings POP may be entirely formed in the first area A1. Each of the pixel openings POP may include the first, second, and third sub-pixel openings SPOP1, SPOP2, and SPOP3 adjacent to each other.

The corner opening COP and the dummy openings DOP may be entirely formed in the second area A2. The corner opening COP may be formed at at least one corner of the second area A2. However, the disclosure is not limited thereto. In another embodiment, the corner openings COP may be formed at all corners. In another embodiment, the corner opening COP is not limited to the corner of the second area A2 and may be formed in a part of the second area A2 including the corner.

The dummy openings DOP may be formed in the second area A2 excluding the corner openings COP. Each of the dummy openings DOP may include the first, second, and third sub-dummy openings SDOP1, SDOP2, and SDOP3 adjacent to each other.

In an embodiment, the corner opening COP may have a shape different from a shape of each of the dummy openings DOP and the pixel openings POP. The corner opening COP may have a larger area than each of the dummy openings DOP and the pixel openings POP.

The alignment mark AM disposed in the corner opening COP may be formed simultaneously with the bank portion BK. Specifically, when the openings OP are formed in the bank portion BK, the alignment mark AM may be formed in the corner opening COP. For example, the bank portion BK and the alignment mark AM may be integral.

In an embodiment, the bank portion BK and the alignment mark AM may be formed using a slit mask. For example, when the openings OP and the alignment mark AM are formed by patterning the bank portion BK, they may be formed using the slit mask. The slit may be applied only to a mask part where the alignment mark AM is formed. By using the slit mask, the exposure amount of the alignment mark AM in the bank portion BK may be adjusted. Through this, the liquid repellency of the bank portion BK and the alignment mark AM may be different. For example, the liquid repellency of the alignment mark AM may be lowered, defects may be prevented from occurring due to misplacement of ink on the alignment mark AM.

FIG. 21 is a schematic enlarged plan view of area D of FIG. 20.

Referring further to FIG. 21, in an embodiment, the center part of the alignment mark AM may be formed on the same line in the first direction DR1 as the center part of the opening adjacent to the corner opening COP among the plurality of openings OP in the first direction DR1. The center part of the alignment mark AM may be formed on the same line in the second direction DR2 as the center part of the opening adjacent to the corner opening COP among the plurality of openings OP in the second direction DR2.

For example, forming the alignment mark AM may include forming the first, second, and third alignment patterns AP1, AP2, and AP3 adjacent to each other. Each of the first, second, and third alignment patterns AP1, AP2, and AP3 may have a cross shape. However, the disclosure is not limited thereto.

The first alignment pattern AP1 may be formed to overlap the first sub-dummy openings SDOP1 in the first and second directions DR1 and DR2. Specifically, the center part of the first alignment pattern AP1 may be formed on the same line in the first direction DR1 as the center part of the first sub-dummy opening SDOP1 adjacent in the first direction DR1. The center part of the first alignment pattern AP1 may be formed on the same line in the second direction DR2 as the center part of the first sub-dummy opening SDOP1 adjacent in the second direction DR2.

The second alignment pattern AP2 may be formed to overlap the second sub-dummy openings SDOP2 in the first and second directions DR1 and DR2. Specifically, the center part of the second alignment pattern AP2 may be formed on the same line in the first direction DR1 as the center part of the second sub-dummy opening SDOP2 adjacent in the first direction DR1. The center part of the second alignment pattern AP2 may be formed on the same line in the second direction DR2 as the center part of the second sub-dummy opening SDOP2 adjacent in the second direction DR2.

The third alignment pattern AP3 may be formed to overlap the third sub-dummy openings SDOP3 in the first and second directions DR1 and DR2. Specifically, the center part of the third alignment pattern AP3 may be formed on the same line in the first direction DR1 as the center part of the third sub-dummy opening SDOP3 adjacent in the first direction DR1. The center part of the third alignment pattern AP3 may be formed on the same line in the second direction DR2 as the center part of the third sub-dummy opening SDOP3 adjacent in the second direction DR2.

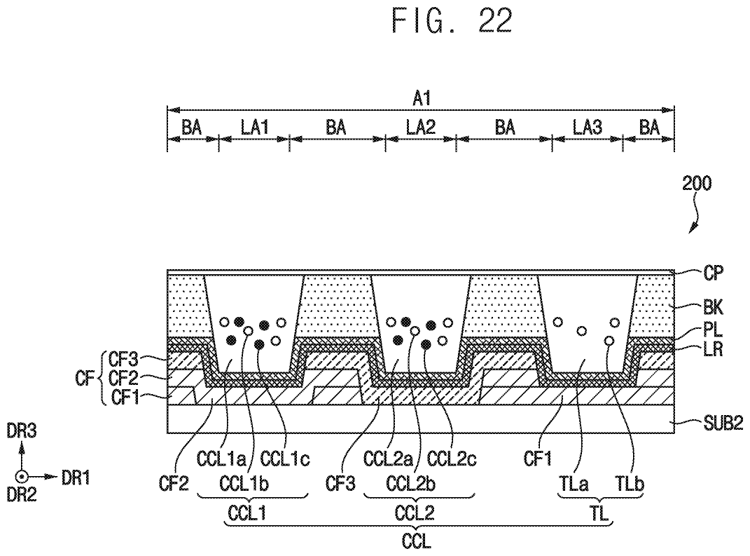

Further referring to FIG. 22, the color conversion layer CCL may be formed in the openings OP overlapping the first and second areas A1 and A2. The color conversion layer CCL may include quantum dots. The color conversion layer CCL may be formed through the inkjet process. During the inkjet process of forming the color conversion layer CCL, the inkjet process may start from the position of the alignment mark AM.

The capping layer CP may be formed on the color conversion layer CCL. Through this, the second substrate 200 may be formed.

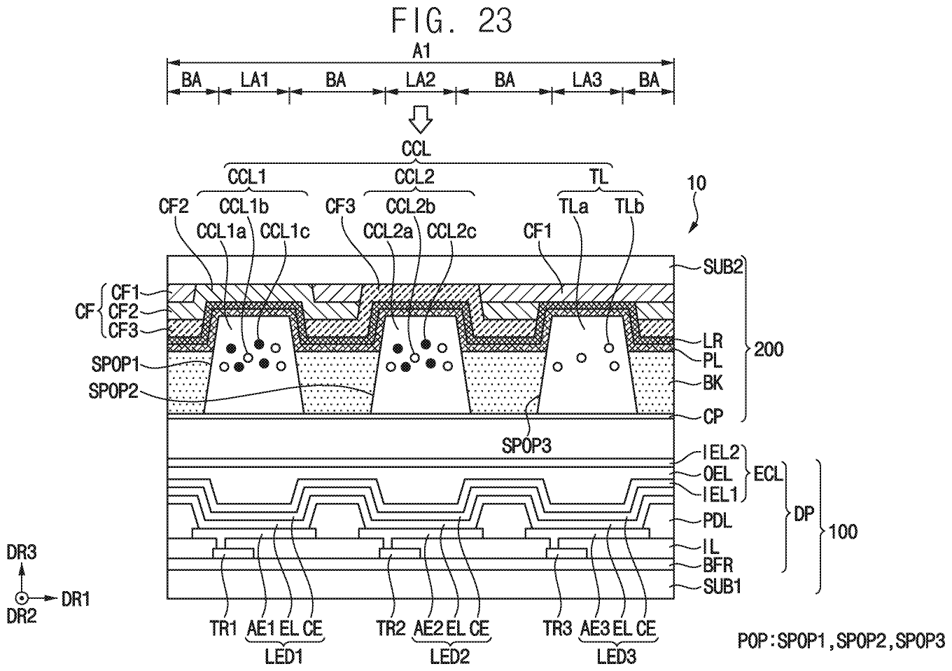

Further referring to FIG. 23, the first base substrate SUB1 and the second base substrate SUB2 may be bonded. For example, the first substrate 100 and the second substrate 200 may be bonded. A sealing member (e.g., the sealing member SLM of FIG. 2) may be formed between the first substrate 100 and the second substrate 200 so that the first substrate 100 and the second substrate 200 can be combined. Through this, the display device 10 may be formed.

However, the disclosure is not limited thereto, and in another embodiment, the first substrate 100 excluding the second substrate 200 may further include the bank portion BK and the color conversion layer CCL (see FIG. 4).

In an embodiment, the alignment mark AM may be further formed in the corner opening COP of the bank portion BK. Therefore, during the inkjet process of forming the color conversion layer CCL, the inkjet process may start from the position of the alignment mark AM. When the color conversion layer CCL is formed by the inkjet apparatus, the position of the inkjet apparatus may be corrected using the alignment mark AM whenever ink is printed on the openings OP of the bank portion BK. Accordingly, defects of the display device 10 due to misplacement of the ink during the inkjet process may be prevented and reliability of the display device 10 may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first area, a second area surrounding the first area, and a third area surrounding the second area;
a first base substrate;
a display structure disposed on the first base substrate in the first area;
a second base substrate facing the first base substrate;
a bank portion disposed between the first base substrate and the second base substrate in the first and second areas and including a plurality of openings in the first and second areas;
a color conversion layer disposed in the plurality of openings; and
an alignment mark disposed in a corner opening among the plurality of openings disposed at at least one edge of the second area, positioned on a same line in a first direction as a center part of an opening adjacent to the corner opening among the plurality of openings in the first direction, and having a center part positioned on a same line in a second direction as a center part of an opening adjacent to the corner opening among the plurality of openings in the second direction intersecting the first direction.

2. The display device of claim 1, wherein the plurality of openings include:
the corner opening at at least one corner of the second area;
dummy openings in the second area excluding the corner opening; and
pixel openings entirely overlapping the first area.

3. The display device of claim 2, wherein
each of the pixel openings includes first, second, and third sub-pixel openings adjacent to each other, and
each of the dummy openings includes first, second, and third sub-dummy openings adjacent to each other.

4. The display device of claim 3, wherein
a shape of the corner opening is different from a shape of each of the first, second, and third sub-dummy openings, and
an area of the corner opening is larger than an area of each of the first, second, and third sub-dummy openings in a plan view.

5. The display device of claim 3, wherein the alignment mark includes first, second, and third alignment patterns adjacent to each other.

6. The display device of claim 5, wherein
a center part of the first alignment pattern is positioned on a same line in the first direction as a center part of the first sub-dummy openings adjacent in the first direction and is positioned on a same line in the second direction as a center part of the first sub-dummy opening adjacent in the second direction,
a center part of the second alignment pattern is positioned on a same line in the first direction as a center part of the second sub-dummy openings adjacent in the first direction and is positioned on a same line in the second direction as a center part of the second sub-dummy opening adjacent in the second direction, and
a center part of the third alignment pattern is positioned on a same line in the first direction as a center part of the third sub-dummy openings adjacent in the first direction and is positioned on a same line in the second direction as a center part of the third sub-dummy opening adjacent in the second direction.

7. The display device of claim 5, wherein each of the first, second, and third alignment pattern has a cross shape.

8. The display device of claim 1, further comprising:
a sealing member disposed between the first base substrate and the second base substrate.

9. The display device of claim 8, wherein the sealing member is disposed in the third area.

10. The display device of claim 1, wherein the alignment mark includes a same material as the bank portion.

11. The display device of claim 1, wherein the bank portion and the alignment mark are integral with each other.

12. The display device of claim 1, wherein the color conversion includes quantum dots.

13. A display device comprising:
a first area, a second area surrounding the first area, and a third area surrounding the second area;
a first base substrate;
a display structure disposed on the first base substrate in the first area;
a second base substrate facing the first base substrate;
a bank portion disposed between the first base substrate and the second base substrate in the first and second areas and including a plurality of openings in the first and second areas;
a color conversion layer disposed in the plurality of openings; and
an alignment mark disposed in a corner opening among the plurality of openings disposed at at least one corner of the second area and protruding in a direction from the bank portion to the corner opening.

14. The display device of claim 13, wherein the alignment mark is integral with the bank portion.

15. The display device of claim 13, wherein the plurality of openings include:
the corner opening at at least one corner of the second area;
dummy openings in the second area excluding the corner opening; and
pixel openings entirely overlapping the first area.

16. The display device of claim 15, wherein
the corner opening includes first, second, and third sub-corner openings adjacent to each other,
each of the pixel openings includes first, second, and third sub-pixel openings adjacent to each other, and
each of the dummy openings includes first, second, and third sub-dummy openings adjacent to each other.

17. The display device of claim 16, wherein shapes of the first, second, and third sub-corner openings are a same as shapes of the first, second, and third sub-dummy openings, respectively.

18. The display device of claim 16, wherein the alignment mark includes at least one alignment pattern disposed in each of the first, second, and third sub-corner openings.

19. The display device of claim 18, wherein a shape of the alignment pattern is a triangle or a quadrangle.

20. The display device of claim 13, wherein the alignment mark protrudes from a side surface of the bank portion.

21. A method of manufacturing a display device, the method comprising:
forming a display structure on a first base substrate in a first area;
forming a bank portion on a second base substrate, the bank portion including a plurality of openings in the first area and a second area surrounding the first area;
forming an alignment mark disposed in a corner opening among the plurality of openings disposed at at least one edge of the second area, positioned on a same line in a first direction as a center part of an opening adjacent to the corner opening among the plurality of openings in the first direction, and having a center part positioned on a same line in a second direction as a center part of an opening adjacent to the corner opening among the plurality of openings in the second direction intersecting the first direction;
forming a color conversion layer in the plurality of openings in the first and second areas; and
adhering the first base substrate and the second base substrate.

22. The method of claim 21, wherein the bank portion and the alignment mark are integral with each other.

23. The method of claim 21, wherein the forming of the bank portion and the forming of the alignment mark are simultaneously performed.

24. The method of claim 21, wherein the bank portion and the alignment mark are formed using a slit mask.

25. The method of claim 21, wherein the plurality of openings include:
the corner opening formed at at least one corner of the second area;
dummy openings formed in the second area excluding the corner opening; and
pixel openings entirely overlapping the first area.

26. The method of claim 25, wherein
each of the pixel openings includes first, second, and third sub-pixel openings adjacent to each other, and
each of the dummy openings includes first, second, and third sub-dummy openings adjacent to each other.

27. The method of claim 26, wherein
the forming of the alignment mark includes forming first, second, and third alignment patterns adjacent to each other,
a center part of the first alignment pattern is formed on a same line in the first direction as a center part of the first sub-dummy openings adjacent in the first direction and is formed on a same line in the second direction as a center part of the first sub-dummy opening adjacent in the second direction,
a center part of the second alignment pattern is formed on a same line in the first direction as a center part of the second sub-dummy openings adjacent in the first direction and is formed on a same line in the second direction as a center part of the second sub-dummy opening adjacent in the second direction, and
a center part of the third alignment pattern is formed on a same line in the first direction as a center part of the third sub-dummy openings adjacent in the first direction and is formed on a same line in the second direction as a center part of the third sub-dummy opening adjacent in the second direction.

28. The method of claim 21, wherein the color conversion layer is formed by an inkjet process.
